(19) United States
(12) Patent Application Publication
(10) Pub. No.: US 2022/0413385 A1
(43) Pub. Date: Dec. 29, 2022

(54) RADIATION-SENSITIVE RESIN COMPOSITION AND METHOD OF FORMING RESIST PATTERN

(71) Applicant: JSR CORPORATION, Tokyo (JP)

(72) Inventors: Kazuya KIRIYAMA, Toyota (JP); Takuhiro Taniguchi, Tokyo (JP); Katsuaki Nishikori, Tokyo (JP); Natsuko Kinoshita, Tokyo (JP)

(73) Assignee: JSR CORPORATION, Tokyo (JP)

(21) Appl. No.: 17/829,432

(22) Filed: Jun. 1, 2022

(30) Foreign Application Priority Data
Jun. 2, 2021 (JP) 2021-093257
Apr. 12, 2022 (JP) 2022-065851

(51) Int. Cl. G03F 7/038; G03F 7/20; G03F 7/32

(52) U.S. Cl. CPC G03F 7/038; G03F 7/20; G03F 7/32

(57) ABSTRACT

The radiation-sensitive resin composition contains: a polymer, solubility of which in a developer solution is capable of being altered by an action of an acid, and which has a structural unit represented by the following formula (1); and a radiation-sensitive acid generating agent. L represents a single bond, —COO—, —O—, or —CONH—. X represents a single bond, —O—, -G-O—, —CH₂—, —S—, —SO₂—, —NR^{A}—, or —CONH—, wherein G represents a divalent aliphatic hydrocarbon group having 1 to 20 carbon atoms, and R^{A} represents a hydrogen atom or a monovalent hydrocarbon group having 1 to 10 carbon atoms. R² and R³ each independently represent a halogen atom, a hydroxy group, a sulfanyl group, or an organic group having 1 to 20 carbon atoms.

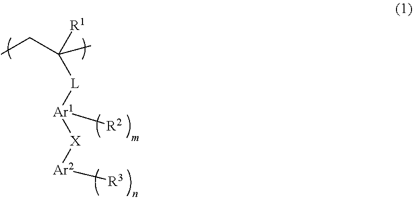

### CROSS-REFERENCE TO RELATED APPLICATIONS

The present application claims priority to Japanese Patent Application No. 2021-093257 filed Jun. 2, 2021, and to Japanese Patent Application No. 2022-065851 filed Apr. 12, 2022. The contents of these applications are incorporated herein by reference in their entirety.

### BACKGROUND OF THE INVENTION

### Field of the Invention

The present invention relates to a radiation-sensitive resin composition and a method of forming a resist pattern.

### Discussion of the Background

A radiation-sensitive resin composition for use in microfabrication by lithography generates an acid at light-exposed regions upon an irradiation with a radioactive ray, e.g., an electromagnetic wave such as a far ultraviolet ray such as an ArF excimer laser beam (wavelength of 193 nm), a KrF excimer laser beam (wavelength of 248 nm), etc. or an extreme ultraviolet ray (EUV) (wavelength of 13.5 nm), or a charged particle ray such as an electron beam. A chemical reaction in which the acid serves as a catalyst causes a difference between the light-exposed regions and light-unexposed regions in rates of dissolution in a developer solution, whereby a resist pattern is formed on a substrate.

Such a radiation-sensitive resin composition is required not only to have favorable sensitivity to exposure light such as an extreme ultraviolet ray and an electron beam, but also to have superiority in terms of LWR (Line Width Roughness) performance and CDU (Critical Dimension Uniformity) performance.

Types, molecular structures, and the like of polymers, acid generating agents, and other components which may be used in radiation-sensitive resin compositions have been investigated to meet these requirements, and combinations thereof have been further investigated in detail (see Japanese Unexamined Patent Applications, Publication Nos. 2010-134279, 2014-224984, and 2016-047815).

### SUMMARY OF THE INVENTION

According to an aspect of the present invention, a radiation-sensitive resin composition includes: a polymer, solubility of which in a developer solution is capable of being altered by an action of an acid, and which comprises a structural unit represented by formula (1); and a radiation-sensitive acid generating agent.

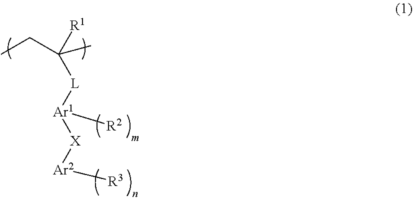

In the formula (1), R¹ represents a hydrogen atom, a methyl group, or a trifluoromethyl group; L represents a single bond, —COO—, —O—, or —CONH—; Ar¹ represents a group obtained by removing (m+2) hydrogen atoms from an aromatic ring having 6 to 30 ring atoms; X represents a single bond, —O—, -G-O—, —CH₂—, —S—, —SO₂—, —NR^{A}—, or —CONH—, wherein G represents a divalent aliphatic hydrocarbon group having 1 to 20 carbon atoms, and R^{A} represents a hydrogen atom or a monovalent hydrocarbon group having 1 to 10 carbon atoms; Ar² represents a group obtained by removing (n+1) hydrogen atoms from an aromatic ring having 6 to 30 ring atoms; R² and R³ each independently represent a halogen atom, a hydroxy group, a sulfanyl group, or an organic group having 1 to 20 carbon atoms; m is an integer of 0 to 10, wherein in a case in which m is no less than 2, a plurality of R²s are identical or different from each other; and n is an integer of 0 to 10, wherein in a case in which n is no less than 2, a plurality of R³s are identical or different from each other.

According to another aspect of the present invention, a method of forming a resist pattern, includes: applying the above-described radiation-sensitive resin composition directly or indirectly on a substrate; exposing a resist film formed by the applying; and developing the resist film exposed.

### DESCRIPTION OF THE EMBODIMENTS

As used herein, the words “a” and “an” and the like carry the meaning of “one or more.” _When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

According to one embodiment of the invention, a radiation-sensitive resin composition contains:

a polymer (hereinafter, may be also referred to as “(A) polymer” or “polymer (A)”), solubility of which in a developer solution is capable of being altered by an action of an acid, and which had a structural unit represented by the following formula (1); and

a radiation-sensitive acid generating agent (hereinafter, may be also referred to as “(B) acid generating agent” or “acid generating agent (B)”).

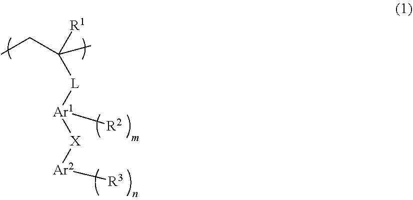

In the formula (1), R¹ represents a hydrogen atom, a methyl group, or a trifluoromethyl group; L represents a single bond, —COO—, —O—, or —CONH—; Ar¹ represents a group obtained by removing (m+2) hydrogen atoms from an aromatic ring having 6 to 30 ring atoms; X represents a single bond, —O—, -G-O—, —CH₂—, —S—, —SO₂—, —NR^{A}—, or —CONH—, wherein G represents a divalent aliphatic hydrocarbon group having 1 to 20 carbon atoms, and R^{A} represents a hydrogen atom or a monovalent hydrocarbon group having 1 to 10 carbon atoms; Ar² represents a group obtained by removing (n+1) hydrogen atoms from an aromatic ring having 6 to 30 ring atoms; R² and R³ each independently represent a halogen atom, a hydroxy group, a sulfanyl group, or an organic group having 1 to 20 carbon atoms; m is an integer of 0 to 10, wherein in a case in which m is no less than 2, a plurality of R²s are identical or different from each other; and n is an integer of 0 to 10, wherein in a case in which n is no less than 2, a plurality of R³s are identical or different from each other.

According to another embodiment of the present invention, a method of forming a resist pattern includes: applying a radiation-sensitive resin composition directly or indirectly on a substrate; exposing a resist film formed by the applying; and developing the resist film exposed, wherein the radiation-sensitive resin composition is the radiation-sensitive resin composition of the one embodiment of the present invention.

Under current circumstances in which microfabrication of resist patterns has reached to a level of the line widths being no greater than 40 nm, required levels for the aforementioned types of performance are further elevated.

The radiation-sensitive resin composition and the method of forming a resist pattern of the embodiments of the present invention enable a resist pattern to be formed with favorable sensitivity to exposure light and superiority in terms of LWR performance and CDU performance. Therefore, the radiation-sensitive resin composition and the method of forming a resist pattern can be suitably used for working processes of semiconductor devices, and the like, in which microfabrication is expected to be further in progress hereafter.

Hereinafter, the radiation-sensitive resin composition and the method of forming a resist pattern according to the embodiments of the present invention will be described in detail.

### Radiation-Sensitive Resin Composition

The radiation-sensitive composition of the one embodiment of the present invention contains the polymer (A) and the acid generating agent (B). The radiation-sensitive resin composition typically contains an organic solvent (hereinafter, may be also referred to as “(D) organic solvent” or “organic solvent (D)”). The radiation-sensitive composition may contain, as a favorable component, an acid diffusion control agent (hereinafter, may be also referred to as “(C) acid diffusion control agent” or “acid diffusion control agent (C)”). The radiation-sensitive resin composition may contain, as a favorable component, a polymer (hereinafter, may be also referred to as “(E) polymer” or “polymer (E)”) having a mass percentage content of fluorine atoms greater than that of the polymer (A). The radiation-sensitive resin composition may contain, within a range not leading to impairment of the effects of the present invention, other optional component(s).

Due to the polymer (A) and the acid generating agent (B) being contained, the radiation-sensitive resin composition enables a resist pattern to be formed with favorable sensitivity to exposure light and superiority in terms of the LWR performance and the CDU performance. Although not necessarily clarified and without wishing to be bound by any theory, the reason for achieving the aforementioned effects by the radiation-sensitive resin composition due to involving such a constitution may be presumed, for example, as in the following. It is believed that due to the polymer (A) being contained in the radiation-sensitive resin composition and having the structural unit represented by the above formula (1), introduction of substituents having a variety of functions is enabled. It is considered that as a result, the radiation-sensitive resin composition of the one embodiment of the present invention enables a resist pattern to be formed with favorable sensitivity to exposure light and superiority in terms of the LWR performance and the CDU performance.

Each component contained in the radiation-sensitive resin composition is described below.

(A) Polymer

The polymer (A) is a polymer, solubility of which in a developer solution is capable of being altered by an action of an acid and which has a structural unit (hereinafter, may be also referred to as “structural unit (I)”) represented by the formula (1) described later. In general, the feature that solubility in a developer solution is capable of being altered by an action of an acid is exhibited due to the acid-labile group included in the polymer (A). The polymer (A) may have the acid-labile group in the structural unit (I), may further have a structural unit (hereinafter, may be also referred to as “structural unit (II)”) including an acid-labile group as a structural unit that differs from the structural unit (I), or may have both of these.

The polymer (A) preferably further has a structural unit (hereinafter, may be also referred to as “structural unit (III)”) including a phenolic hydroxyl group. The polymer (A) may further have other structural unit(s) (hereinafter, may be also referred to as merely “other structural unit”) aside from the structural units (I) to (III). The polymer (A) may have one, or two or more types of each structural unit. The radiation-sensitive resin composition may contain one, or two or more types of the polymer (A).

Each structural unit contained in the polymer (A) is described below.

Structural Unit (I)

The structural unit (I) is a structural unit represented by the following formula (1). Due to the structural unit (I) being included, introduction of substituents having a variety of functions is enabled without deteriorating efficiency of generation of an acid by an exposure. As a result, the radiation-sensitive resin composition enables a resist pattern to be formed with favorable sensitivity to exposure light and superiority in terms of the LWR performance and the CDU performance.

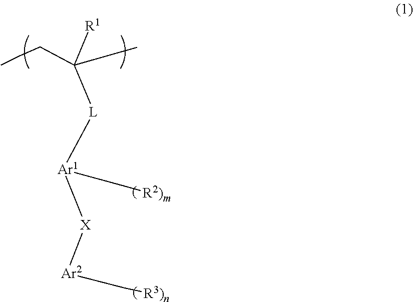

In the formula (1), R¹ represents a hydrogen atom, a methyl group, or a trifluoromethyl group; L represents a single bond, —COO—, —O—, or —CONH—; Ar¹ represents a group obtained by removing (m+2) hydrogen atoms from an aromatic ring having 6 to 30 ring atoms; X represents a single bond, —O—, -G-O—, —CH₂—, —S—, —SO₂—, —NR^{A}—, or —CONH—, wherein G represents a divalent aliphatic hydrocarbon group having 1 to 20 carbon atoms, and R^{A} represents a hydrogen atom or a monovalent hydrocarbon group having 1 to 10 carbon atoms; Ar² represents a group obtained by removing (n+1) hydrogen atoms from an aromatic ring having 6 to 30 ring atoms; R² and R³ each independently represent a halogen atom, a hydroxy group, a sulfanyl group, or an organic group having 1 to 20 carbon atoms; m is an integer of 0 to 10, wherein in a case in which m is no less than 2, a plurality of R²s are identical or different from each other; and n is an integer of 0 to 10, wherein in a case in which n is no less than 2, a plurality of R³s are identical or different from each other.

The number of “ring atoms” as referred to herein means the number of atoms constituting a ring structure, and in the case of a polycyclic ring, the number of “ring atoms” means the number of atoms constituting the polycyclic ring. The “aromatic ring” encompasses an “aromatic hydrocarbon ring” and an “aromatic heterocyclic ring”. The “aromatic ring” encompasses a “monocyclic aromatic ring” and a “polycyclic aromatic ring”. The “polycyclic aromatic ring” may encompass a fused polycyclic rings in which two rings have two shared atoms, as well as a ring-assembled polycyclic ring in which two rings are connected by a single bond without having any shared atom.

The “hydrocarbon group” as referred to herein may be exemplified by a chain hydrocarbon group, an alicyclic hydrocarbon group, and an aromatic hydrocarbon group. The “hydrocarbon group” may be either a saturated hydrocarbon group or an unsaturated hydrocarbon group. The “chain hydrocarbon group” as referred to herein means a hydrocarbon group not including a ring structure but being constituted with only a chain structure, and may be exemplified by both a linear hydrocarbon group and a branched hydrocarbon group. The “alicyclic hydrocarbon group” as referred to herein means a hydrocarbon group including, as a ring structure, not an aromatic ring structure but an alicyclic structure alone, and may be exemplified by both a monocyclic alicyclic hydrocarbon group and a polycyclic alicyclic hydrocarbon group. With regard to this, it is not necessary for the alicyclic hydrocarbon group to be constituted with only an alicyclic structure; it may include a chain structure in a part thereof. The “aromatic hydrocarbon group” as referred to herein means a hydrocarbon group including an aromatic ring structure as a ring structure. With regard to this, it is not necessary for the aromatic hydrocarbon group to be constituted with only an aromatic ring structure; it may include a chain structure or an alicyclic structure in a part thereof. The “aliphatic hydrocarbon group” as referred to herein means a chain hydrocarbon group and an alicyclic hydrocarbon group.

R¹ represents, in light of copolymerizability of a monomer that gives the structural unit (I), preferably a hydrogen atom or a methyl group, and more preferably a hydrogen atom.

L represents preferably a single bond or —COO—.

The aromatic ring having 6 to 30 ring atoms that gives Ar¹ or Ar² is exemplified by an aromatic hydrocarbon having 6 to 30 ring atoms, an aromatic heterocyclic ring having 6 to 30 ring atoms, and the like.

Examples of the aromatic hydrocarbon ring having 6 to 30 ring atoms include: a benzene ring; fused polycyclic aromatic hydrocarbon rings such as a naphthalene ring, a phenanthrene ring, and an anthracene ring; ring-assembled aromatic hydrocarbon rings such as a biphenyl ring, a terphenyl ring, a binaphthalene ring, and a phenylnaphthalene ring; and the like.

Examples of the aromatic heterocyclic ring having 6 to 30 ring atoms include: oxygen atom-containing heterocyclic rings such as a pyran ring, a benzofuran ring, and a benzopyran ring; nitrogen atom-containing heterocyclic rings such as a pyridine ring, a pyrimidine ring, and an indole ring; and the like.

The aromatic ring having 6 to 30 ring atoms that gives Ar¹ or Ar² is preferably an aromatic hydrocarbon ring having 6 to 30 ring atoms, and more preferably a benzene ring or a naphthalene ring.

The aromatic ring that gives Ar¹ and the aromatic ring that gives Ar² may be either the same aromatic ring or different aromatic rings, and are preferably the same aromatic ring.

X represents preferably —O—, -G-O—, —S—, —SO₂— or —NR^{A}—, more preferably —O—, —S— or —SO₂—, and still more preferably —O—.

The divalent aliphatic hydrocarbon group having 1 to 20 carbon atoms represented by G may be exemplified by monovalent chain hydrocarbon groups having 1 to 20 carbon atoms or monovalent alicyclic hydrocarbon groups having 3 to 20 carbon atoms, of groups exemplified as monovalent hydrocarbon groups having 1 to 20 carbon atoms herein below, from which one hydrogen atom has been removed. G represents preferably a divalent chain hydrocarbon group having 1 to 10 carbon atoms or a divalent alicyclic hydrocarbon group having 5 to 20 carbon atoms, more preferably a divalent chain hydrocarbon group having 1 to 4 carbon atoms, and still more preferably a methanediyl group.

The monovalent hydrocarbon group having 1 to 10 carbon atoms which may be represented by R^{A} may be exemplified by groups similar to those having 1 to 10 carbon atoms, of groups exemplified as the monovalent hydrocarbon group having 1 to 20 carbon atoms described later. R^{A} represents preferably a hydrogen atom.

The organic group having 1 to 20 carbon atoms which may be represented by R² or R³ is exemplified by: a monovalent hydrocarbon group having 1 to 20 carbon atoms; a group (α) including a divalent hetero atom-containing group between two adjacent carbon atoms of the monovalent hydrocarbon group; a group (β) obtained by substituting with a monovalent hetero atom-containing group, a part or all of hydrogen atoms included in the monovalent hydrocarbon group or the group (α); a group (γ) in which the monovalent hydrocarbon group, the group (α), or the group (β) is combined with a divalent hetero atom-containing group; and the like.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include: alkyl groups such as a methyl group, an ethyl group, an n-propyl group, and an i-propyl group; alkenyl groups such as an ethenyl group, a propenyl group, and a butenyl group; alkynyl groups such as an ethynyl group, a propynyl group, and a butynyl group; and the like.

Examples of the monovalent alicyclic hydrocarbon group having 3 to 20 carbon atoms include: monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; polycyclic alicyclic unsaturated hydrocarbon groups such as a norbornenyl group, a tricyclodecenyl group, and a tetracyclododecenyl group; and the like.

Examples of the monovalent aromatic hydrocarbon group having 6 to 20 carbon atoms include: aryl groups such as a phenyl group, a tolyl group, a xylyl group, a naphthyl group, and an anthryl group; aralkyl groups such as a benzyl group, a phenethyl group, a naphthylmethyl group, and an anthrylmethyl group; and the like.

The hetero atom that may constitute the monovalent or divalent hetero atom-containing group is exemplified by an oxygen atom, a nitrogen atom, a sulfur atom, a phosphorus atom, a silicon atom, a halogen atom and the like. Examples of the halogen atom include a fluorine atom, a chlorine atom, a bromine atom, and an iodine atom.

Examples of the divalent hetero atom-containing group include —O—, —CO—, —S—, —CS—, —NR′—, groups in which at least two of the aforementioned groups are combined (e.g., —COO—, —CONR′—, and the like), and the like, wherein R′ represents a hydrogen atom or a monovalent hydrocarbon group having 1 to 10 carbon atoms. The monovalent hydrocarbon group having 1 to 10 carbon atoms which may be represented by R′ is exemplified by groups similar to those exemplified in connection with R^{A}, and the like.

The halogen atom which may be represented by R² or R³ is preferably a fluorine atom, a bromine atom, or an iodine atom. In addition, at least one of R² and R³ is preferably a fluorine atom or an iodine atom. In this case, the sensitivity to exposure light, the LWR performance, and the CDU performance resulting from the radiation-sensitive resin composition can be further improved.

In the case in which R² and/or R³ represent(s) the monovalent organic group having 1 to 20 carbon atoms, introduction of substituents having a variety of functions into the polymer (A) is enabled by appropriately selecting the type of the organic group. As a result, forming a resist pattern is enabled with favorable sensitivity to exposure light and superiority in terms of the LWR performance and the CDU performance.

m is preferably 0 to 6, more preferably 1 to 5, and still more preferably 1 to 4. n is preferably 0 to 6, more preferably 1 to 5, and still more preferably 1 to 4. The sum of m and n is preferably no less than 1.

The organic group is preferably a group (hereinafter, may be also referred to as “group (I)”) including an acid-labile group, or a group (hereinafter, may be also referred to as “group (II)”) including a polar group.

Group (I) The group (I) is a group including an acid-labile group. The “acid-labile group” as referred to herein means a group that substitutes for a hydrogen atom in a carboxy group, a hydroxy group or the like, and is capable of being dissociated by an action of an acid to give a carboxy group, a hydroxy group or the like.

In the case in which the organic group is the group (I), the polymer (A) exhibits the feature that solubility in a developer solution is capable of being altered by an action of an acid, due to the acid-labile group included in the group (I). As a result, the acid-labile group is dissociated by an action of the acid generated from the acid generating agent (B), etc. upon exposure, whereby the solubility of the polymer (A) in the developer solution is altered in light-exposed regions, and thus a resist pattern can be formed.

As the group (I), groups (hereinafter, may be also referred to as “group (I-1) to group (I-3)”) represented by the following formulae (I-1) to (I-3) are preferred. For example, in the following formula (I-1), —C(R⁴)(R⁵)(R⁶) corresponds to the acid-labile group.

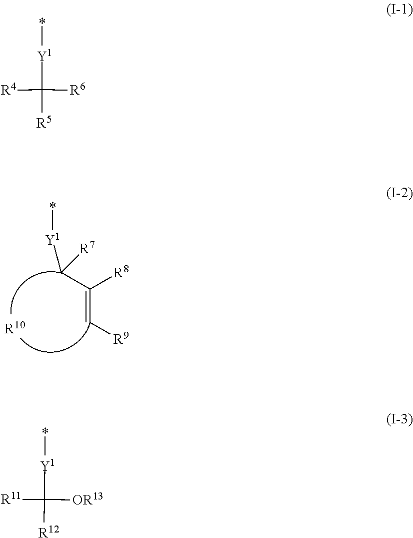

In the above formulae (I-1) to (I-3), * denotes a site bonding to Ar¹ or Ar² in the above formula (1); and Y¹ represents —COO—, —O— or —OCOO—.

In the above formula (I-1), R⁴ represents a monovalent hydrocarbon group having 1 to 20 carbon atoms; and R⁵ and R⁶ each independently represent a monovalent hydrocarbon group having 1 to 20 carbon atoms, or R⁵ and R⁶ taken together represent an alicyclic structure having 3 to 20 ring atoms together with the carbon atom to which R⁵ and R⁶ bond.

In the above formula (I-2), R⁷ represents a hydrogen atom; R⁸ and R⁹ each independently represent a hydrogen atom or a monovalent hydrocarbon group having 1 to 20 carbon atoms; and R¹⁰ represents a divalent hydrocarbon group having 1 to 20 carbon atoms which constitutes an unsaturated alicyclic structure having 4 to 20 ring atoms together with the carbon atoms to which R⁷, R⁸ and R⁹ bond, respectively.

In the above formula (I-3), R¹¹ and R¹² each independently represent a hydrogen atom or a monovalent hydrocarbon group having 1 to 20 carbon atoms, and R¹³ represents a monovalent hydrocarbon group having 1 to 20 carbon atoms, or R¹¹ and R¹² taken together represent an alicyclic structure having 3 to 20 ring atoms, together with the carbon atom to which R¹¹ and R¹² bond, or R¹² and R¹³ taken together represent an aliphatic heterocyclic structure having 5 to 20 ring atoms, together with the carbon atom to which R¹² bonds and the oxygen atom to which R¹³ bonds.

Y¹ represents preferably —COO— or —O—.

Examples of the hydrocarbon group having 1 to 20 carbon atoms which may be represented by R⁴, R⁵, R⁶, R⁸, R⁹, R¹¹, R¹², or R¹³ include groups similar to the hydrocarbon groups exemplified as R² and R³ in the above formula (1).

Examples of the alicyclic structure having 3 to 20 ring atoms which may be represented by R⁵ and R⁶ or R¹¹ and R¹² taken together, together with the carbon atom to which R⁵ and R⁶ or R¹¹ and R¹² bond include: monocyclic saturated alicyclic structures such as a cyclopropane structure, a cyclobutane structure, a cyclopentane structure, and a cyclohexane structure; polycyclic saturated alicyclic structures such as a norbornane structure and an adamantane structure; monocyclic unsaturated alicyclic structures such as a cyclopropene structure, a cyclobutene structure, a cyclopentene structure, and a cyclohexene structure; polycyclic unsaturated alicyclic structures such as a norbornene structure; and the like.

Examples of the divalent hydrocarbon group having 1 to 20 carbon atoms represented by R¹⁰ include groups obtained by removing one hydrogen atom from the monovalent hydrocarbon group exemplified as R² and R³ in the above formula (1), and the like.

Examples of the unsaturated alicyclic structure having 4 to 20 ring atoms which is constituted by R¹⁰ together with the carbon atoms to which R⁷, R⁸ and R⁹ bond, respectively include structures similar to those having 4 to 20 ring atoms exemplified as the unsaturated alicyclic structures, of the alicyclic structures having 3 to 20 ring atoms which may be represented by R⁵ and R⁶ or R¹¹ and R¹² taken together, together with the carbon atom to which R⁵ and R⁶ or R¹¹ and R¹² bond.

Examples of the aliphatic heterocyclic structure having 5 to 20 ring atoms which may be represented by R¹² and R¹³ taken together, together with the carbon atom to which R¹² bonds and the oxygen atom to which R¹³ bonds, include: saturated oxygen-containing heterocyclic structures such as an oxacyclobutane structure, an oxacyclopentane structure, and an oxacyclohexane structure; unsaturated oxygen-containing heterocyclic structures such as an oxacyclobutene structure, an oxacyclopentene structure, and an oxacyclohexene structure; and the like.

R⁴ represents preferably the chain hydrocarbon group or the aromatic hydrocarbon group, more preferably the alkyl group or the aryl group, and still more preferably a methyl group, an ethyl group, or a phenyl group.

R⁵ and R⁶ each represent preferably the chain hydrocarbon group, more preferably the alkyl group or the alkenyl group, and still more preferably a methyl group or an ethenyl group. Alternatively, it is preferred that R⁵ and R⁶ taken together represent the alicyclic structure having 3 to 20 ring atoms together with the carbon atom to which R⁵ and R⁶ bond, wherein the alicyclic structure is preferably the saturated alicyclic structure, more preferably the monocyclic saturated alicyclic structure or the polycyclic saturated alicyclic structure, and still more preferably a cyclopentane structure or an adamantane structure.

R⁸ and R⁹ each represent preferably a hydrogen atom or the chain hydrocarbon group, more preferably a hydrogen atom or the alkyl group, still more preferably a hydrogen atom or a methyl group, and particularly preferably a hydrogen atom.

The unsaturated alicyclic structure having 4 to 20 ring atoms constituted by R¹⁰, together with the carbon atoms to which R⁷, R⁸ and R⁹ bond, respectively, is preferably a cyclohexene structure.

R¹¹ represents preferably a hydrogen atom.

It is preferred that R¹² and R¹³ taken together represent the aliphatic heterocyclic structure having 5 to 20 ring atoms, together with the carbon atom to which R¹² bonds and the oxygen atom to which R¹³ bonds, wherein the aliphatic heterocyclic structure is preferably a saturated oxygen-containing heterocyclic structure, and more preferably an oxacyclohexane structure.

Examples of the group (I-1) include groups (hereinafter, may be also referred to as “group (I-1-1) to group (I-1-7)”) represented by the following formulae (I-1-1) to (I-1-7), and the like.

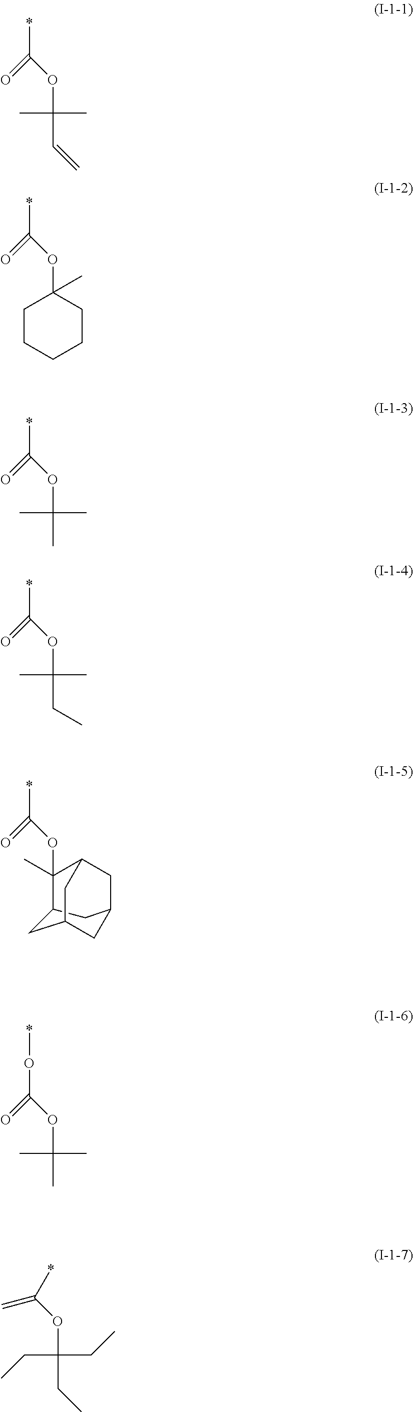

In the above formulae (I-1-1) to (I-1-7), * is as defined in the above formula (I-1).

Examples of the group (I-2) include a group (hereinafter, may be also referred to as “group (I-2-1)”) represented by the following formula (I-2-1), and the like.

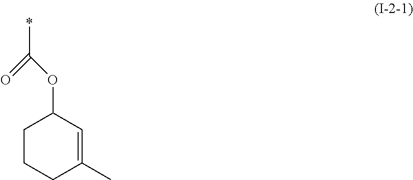 [SMILES: *C(=O)OC1C=C(C)CCC1]

In the above formula (I-2-1), * is as defined in the above formula (I-2).

Examples of the group (I-3) include a group (hereinafter, may be also referred to as “group (I-3-1)”) represented by the following formula (I-3-1), and the like.

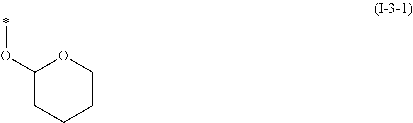 [SMILES: *OC1CCCCO1]

In the above formula (I-3-1), * is as defined in the above formula (I-3).

The group (I) is preferably the group (I-1) or the group (I-2), and more preferably the group (I-1).

Group (II)

The group (II) is a group including a polar group. The polar group is exemplified by a group including a lactone ring structure or a cyclic carbonate structure, a group that gives a hydroxy group by hydrolysis, a fluorinated alcohol group, a ketone group, an alkoxy group, and the like.

Examples of the group (II) include a group (hereinafter, may be also referred to as “group (II-1)”) represented by the following formula (II-1).

*—Y²—R¹⁴ (II-1)

In the above formula (II), * denotes a site bonding to Ar¹ or Ar² in the above formula (1); Y² represents a single bond, —COO— or —O—; and R¹⁴ represents the polar group.

Examples of the group (II-1) include groups represented by the following formulae (II-1-1) to (II-1-7), and the like. It is to be noted that the group represented by the following formula (II-1-1) is a specific example in the case of the polar group being the group including a cyclic carbonate structure; the group represented by the following formula (II-1-2) is a specific example in the case of the polar group being the group including a lactone ring structure; the group represented by the following formula (II-1-3) is a specific example in the case of the polar group being the group that gives a hydroxy group by hydrolysis; the group represented by the following formula (II-1-4) is a specific example in the case of the polar group being the fluorinated alcohol group; the group represented by the following formula (II-1-5) is a specific example in the case of the polar group being the ketone group; and the group represented by the following formula (II-1-6) is a specific example in the case of the polar group being the alkoxy group.

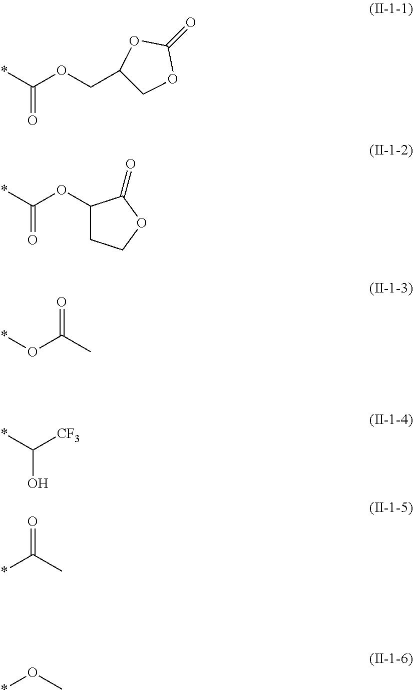

In the above formulae (II-1-1) to (II-1-7), * is as defined in the above formula (II-1).

The polar group is preferably the group including a lactone ring structure or a cyclic carbonate structure, the group that gives a hydroxy group by hydrolysis, or the fluorinated alcohol group, and more preferably the group including a lactone ring structure or a cyclic carbonate structure or the group that gives a hydroxy group by hydrolysis.

The lower limit of a proportion of the structural unit (I) in the polymer (A) with respect to total structural units constituting the polymer (A) is preferably 1 mol %, and more preferably 5 mol %. The upper limit of the proportion is preferably 60 mol %, and more preferably 50 mol %. When the proportion of the structural unit (I) falls within the above range, the sensitivity to exposure light, the LWR performance, and the CDU performance resulting from the radiation-sensitive resin composition can be further improved.

Structural Unit (II)

The structural unit (II) is a structural unit including an acid-labile group.

In the case in which the polymer (A) has the structural unit (II), the polymer (A) exhibits the feature that solubility in a developer solution is capable of being altered by an action of an acid, due to the acid-labile group included in the structural unit (II). As a result, the acid-labile group is dissociated by an action of the acid generated from the acid generating agent (B), etc. upon exposure, whereby the solubility of the polymer (A) in the developer solution is altered in light-exposed regions, and thus a resist pattern can be formed.

Examples of the structural unit (II) include a structural unit (hereinafter, may be also referred to as “structural unit (II-1)”) represented by the following formula (3), and the like. It is to be noted that in the following formula (3), —C(R^{X})(R^{Y})(R^{Z}) bonding to the oxyoxygen atom derived from the carboxy group corresponds to the acid-labile group.

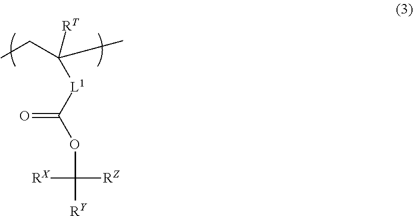

In the above formula (3), R^{T} represents a hydrogen atom, a fluorine atom, a methyl group, or a trifluoromethyl group; R^{X} represents a hydrogen atom or a monovalent hydrocarbon group having 1 to 20 carbon atoms; R^{Y} and R^{Z} each independently represent a monovalent hydrocarbon group having 1 to 20 carbon atoms, or R^{Y} and R^{Z} taken together represent an alicyclic structure having 3 to 20 ring atoms together with the carbon atom to which R^{Y} and R^{Z} bond; and L¹ represents a single bond or a divalent organic group having 1 to 20 carbon atoms.

Examples of the monovalent hydrocarbon group having 1 to 20 carbon atoms which may be represented by R^{X}, R^{Y} or R^{Z} include groups similar to the hydrocarbon groups exemplified as R² and R³ in the above formula (1), and the like.

Examples of the alicyclic structure having 3 to 20 ring atoms which may be represented by R^{Y} and R^{Z} taken together, together with the carbon atom to which R^{Y} and R^{Z} bond include ones similar to those exemplified as the alicyclic structure having 3 to 20 ring atoms which may be represented by R⁵ and R⁶ taken together, together with the carbon atom to which R⁵ and R⁶ bond in the above formula (2-1), and the like.

Examples of the divalent organic group having 1 to 20 carbon atoms which may be represented by L¹ include groups obtained by removing one hydrogen atom from the group exemplified as the organic group having 1 to 20 carbon atoms which may be represented by R² or R³ in the above formula (1), and the like.

R^{T} represents preferably a hydrogen atom or a methyl group, in light of copolymerizability of a monomer that gives a structural unit (II).

R^{X} represents preferably the chain hydrocarbon group or the aromatic hydrocarbon group, and more preferably the alkyl group or the aryl group. The aromatic hydrocarbon group may be substituted with a halogen atom.

It is preferred that: R^{Y} and R^{Z} each represent the chain hydrocarbon group or the alicyclic hydrocarbon group; or R^{Y} and R^{Z} taken together represent the saturated alicyclic structure together with the carbon atom to which R^{Y} and R^{Z} bond.

L¹ represents preferably a single bond or a group in which a divalent hydrocarbon group is combined with a divalent hetero atom-containing group.

The structural unit (II) is preferably one of structural units (hereinafter, may be also referred to as “structural units (II-1) to (II-8)”) represented by the following formulae (3-1) to (3-8).

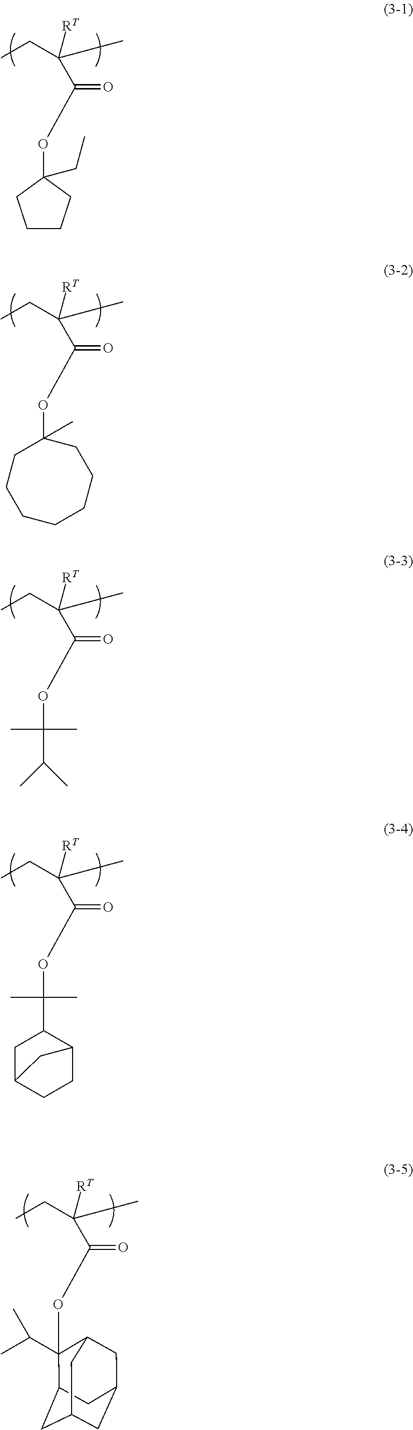

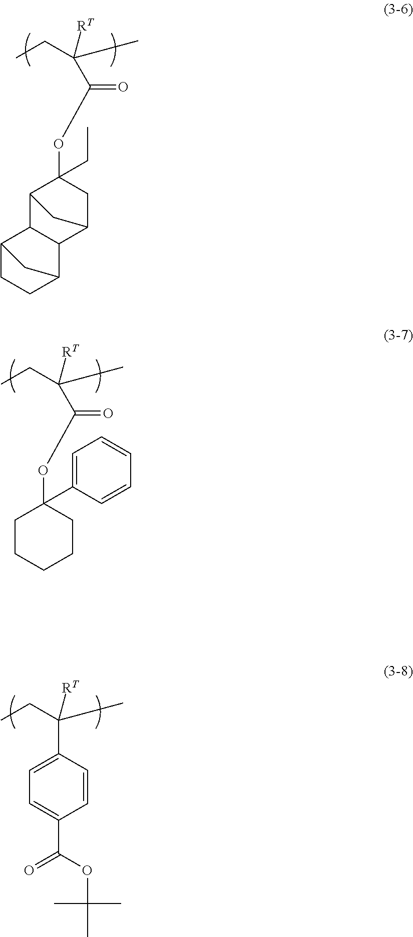

In the above formulae (3-1) to (3-8), R^{T} is as defined in the above formula (3).

The lower limit of a proportion of the structural unit (II) in the polymer (A) with respect to total structural units constituting the polymer (A) is preferably 5 mol %, more preferably 10 mol %, and still more preferably 15 mol %. The upper limit of the proportion is preferably 80 mol %, more preferably 70 mol %, and still more preferably 60 mol %. When the proportion of the structural limit (II) falls within the above range, the sensitivity to exposure light, the LWR performance, and the CDU performance resulting from the radiation-sensitive resin composition can be further improved.

Structural Unit (III)

The structural unit (III) is a structural unit including a phenolic hydroxyl group. The “phenolic hydroxyl group” as referred to herein is not limited to a hydroxy group directly bonding to a benzene ring, and means any hydroxy group directly bonding to an aromatic ring in general.

Due to further having the structural unit (III), the polymer (A) enables increasing the hydrophilicity of the resist film, whereby the solubility in the developer solution can be appropriately adjusted, and additionally, adhesiveness of the resist pattern to a substrate can be improved. Furthermore, in a case in which an extreme ultraviolet ray (EUV) or an electron beam is used as a radioactive ray employed for irradiation in an exposure step of the method of forming a resist pattern described later, the sensitivity to exposure light can be further improved. Therefore, the radiation-sensitive resin composition can be suitably used as a radiation-sensitive resin composition for exposure to an extreme ultraviolet ray or for exposure to an electron beam.

Examples of the structural unit (III) include structural units represented by the following formulae, and the like.

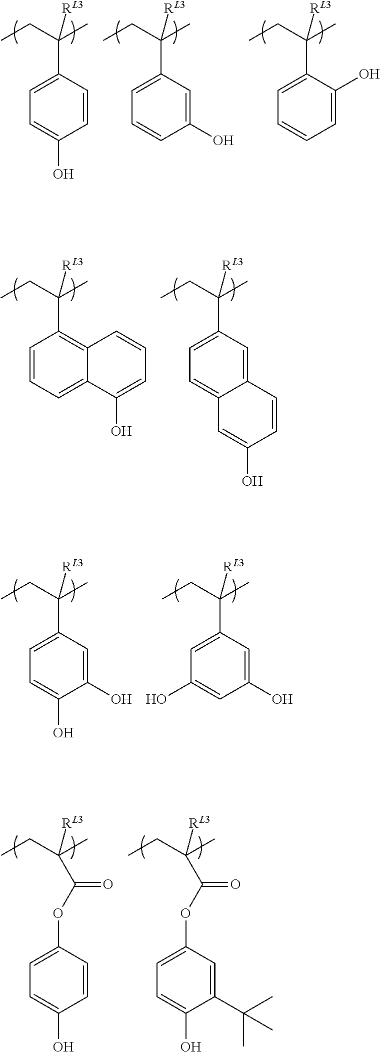

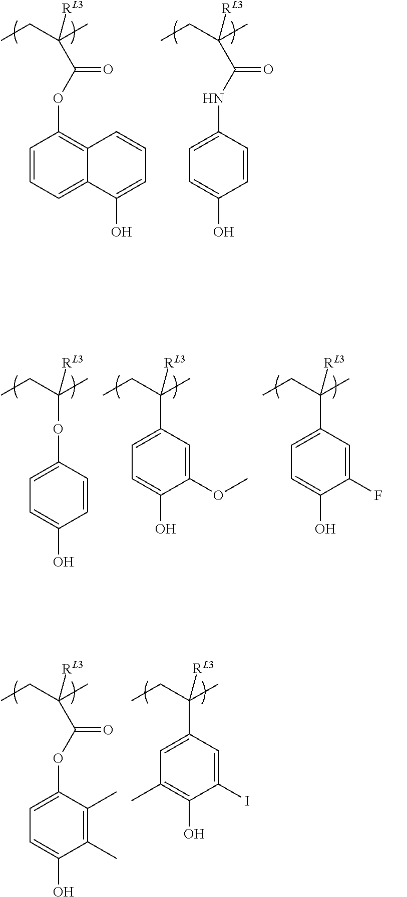

In the above formulae, R^{L3} represents a hydrogen atom, a fluorine atom, a methyl group, or a trifluoromethyl group.

In the case of the polymer (A) having the structural unit (III), the lower limit of a proportion of the structural unit (III) with respect to total structural units in the polymer (A) is preferably 20 mol %, and more preferably 30 mol %. The upper limit of the proportion is preferably 80 mol %, and more preferably 70 mol %.

Other Structural Units

Examples of the other structural unit include a structural unit (hereinafter, may be also referred to as “structural unit (IV)”) including an alcoholic hydroxyl group; a structural unit (hereinafter, may be also referred to as “structural unit (V)”) including a lactone structure, a cyclic carbonate structure, a sultone structure, or a combination thereof; and the like.

Structural Unit (IV)

The structural unit (IV) is a structural unit including an alcoholic hydroxyl group. Due to further having the structural unit (IV), the solubility in a developer solution can be even further appropriately adjusted, and thus, the sensitivity to exposure light resulting from the radiation-sensitive resin composition can be further improved.

Examples of the structural unit (IV) include structural units represented by the following formulae, and the like.

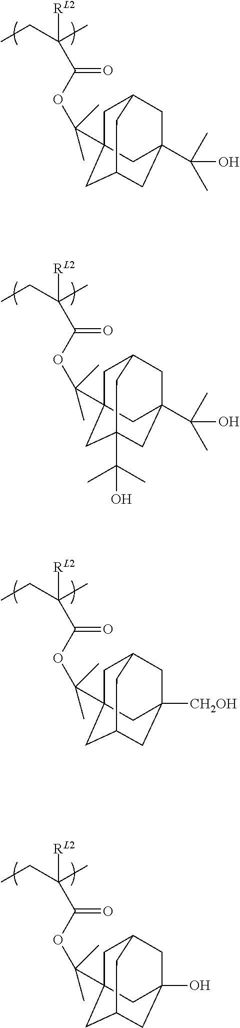

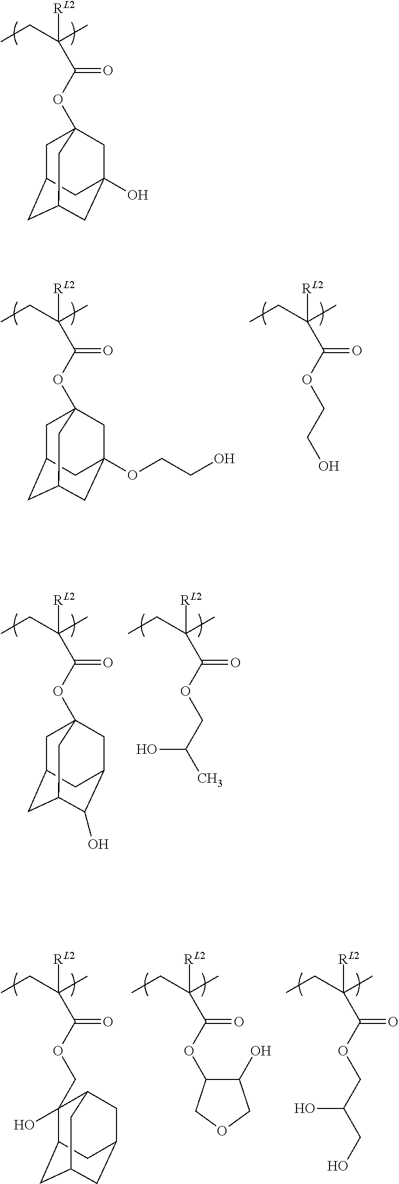

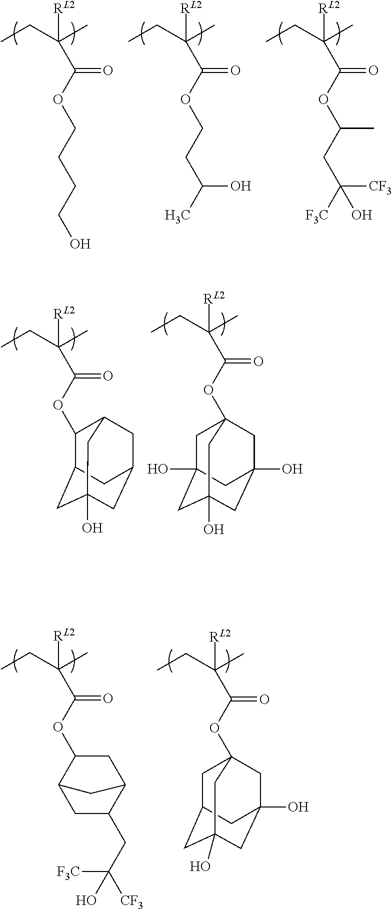

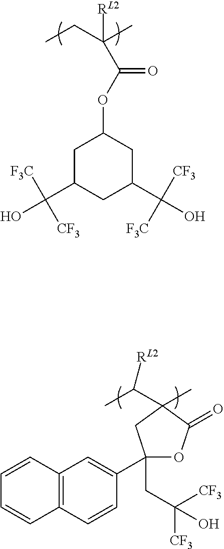

In the above formulae, R^{L2} represents a hydrogen atom, a fluorine atom, a methyl group, or a trifluoromethyl group.

Structural Unit (V)

The structural unit (V) is a structural unit including a lactone structure, a cyclic carbonate structure, a sultone structure, or a combination thereof. Due to further having the structural unit (V), the solubility in a developer solution can be even further appropriately adjusted.

Examples of the structural unit (V) include structural units represented by the following formulae, and the like.

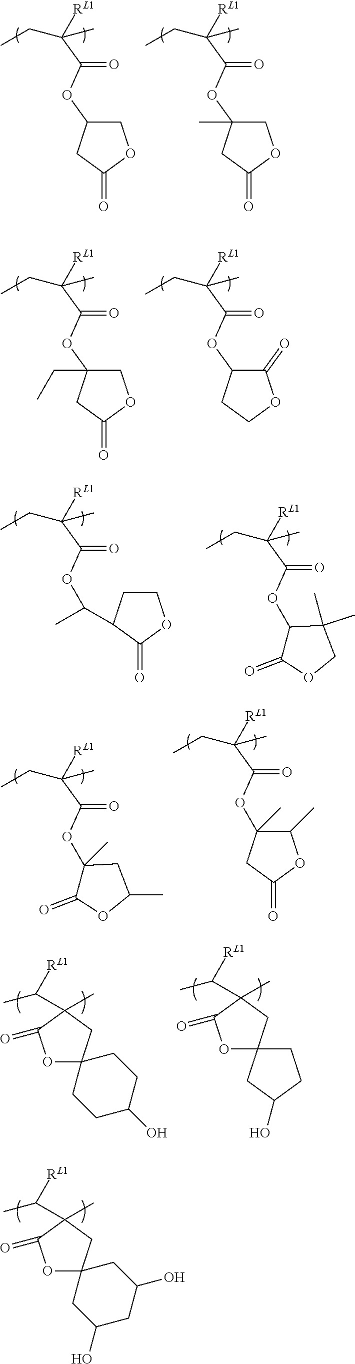

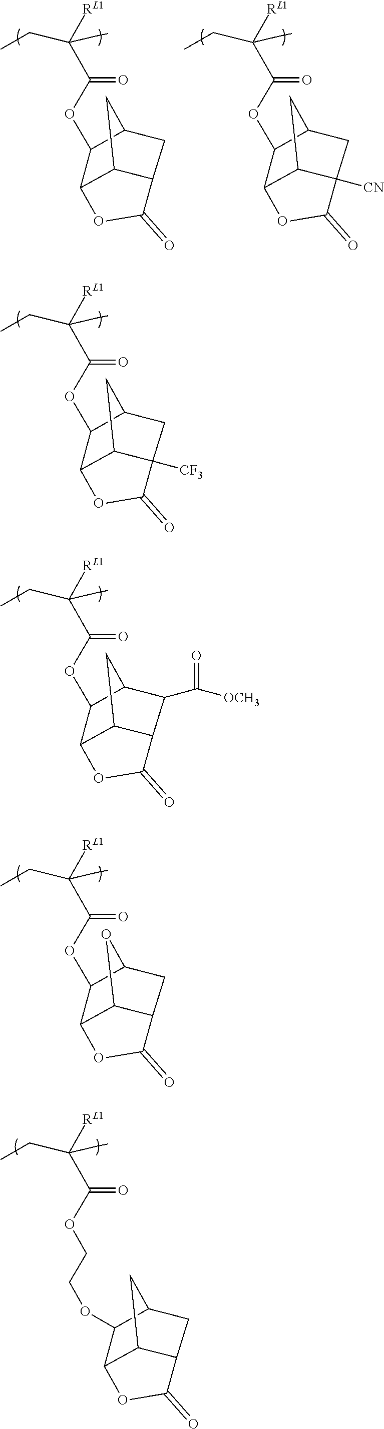

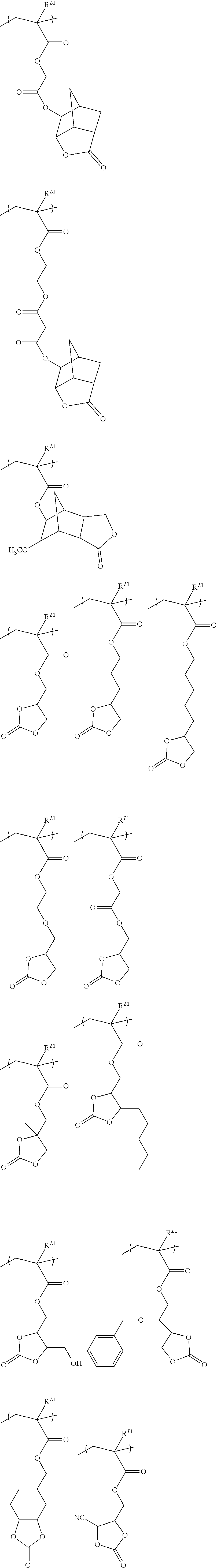

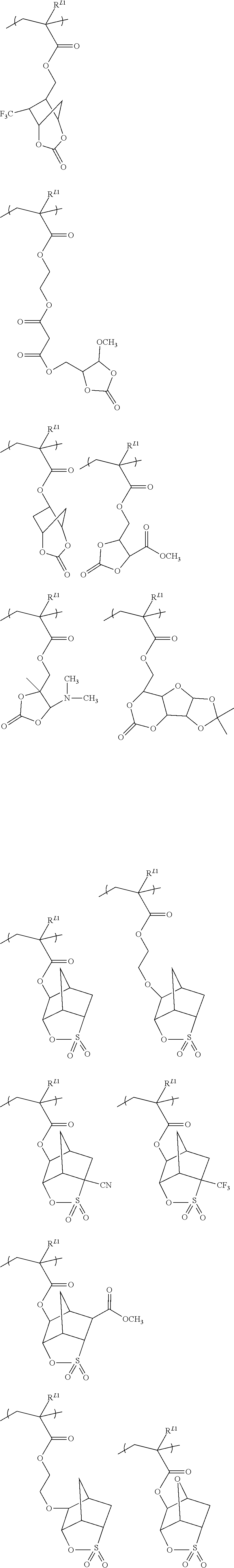

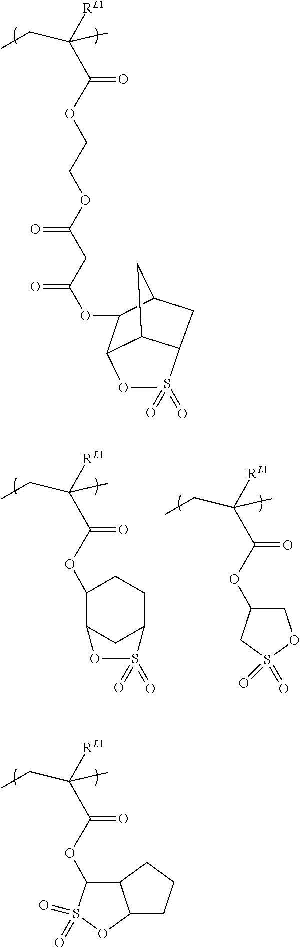

In the above formulae, R^{L1} represents a hydrogen atom, a fluorine atom, a methyl group, or a trifluoromethyl group.

In the case of the polymer (A) having the other structural unit(s), the lower limit of a proportion of the other structural unit(s) with respect to the total structural units in the polymer (A) is preferably 5 mol %, and more preferably 10 mol %. The upper limit of the proportion is preferably 70 mol %, and more preferably 60 mol %.

The lower limit of a polystyrene equivalent weight average molecular weight (Mw) of the polymer (A) as determined by gel permeation chromatography (GPC) is preferably 2,000, more preferably 3,000, and still more preferably 4,000. The upper limit of the Mw is preferably 10,000, more preferably 9,000, and still more preferably 8,000. When the Mw of the polymer (A) falls within the above range, the solubility in a developer solution can be appropriately adjusted.

The upper limit of a ratio (Mw/Mn; hereinafter, may be also referred to as “dispersity index”) of the Mw to a polystyrene-equivalent number average molecular weight (Mn) of the polymer (A) as determined by GPC is preferably 2.50, more preferably 2.00, and still more preferably 1.75. The lower limit of the ratio is typically 1.00, preferably 1.10, and more preferably 1.20. When the Mw/Mn of the polymer (A) falls within the above range, coating characteristics of the radiation-sensitive resin composition can be further improved.

As referred to herein, the Mw and Mn of the polymer are values measured by gel permeation chromatography (GPC) under the following conditions.

GPC columns: “G2000 HXL”×2, “G3000 HXL”×1, and “G4000 HXL”×1, available from Tosoh Corporation

elution solvent: tetrahydrofuran

flow rate: 1.0 mL/min

sample concentration: 1.0% by mass

amount of injected sample: 100 uL

column temperature: 40° C.

detector: differential refractometer

standard substance: mono-dispersed polystyrene

The lower limit of a proportion of the polymer (A) in the radiation-sensitive resin composition with respect to total components other than the organic solvent (D) is preferably 50% by mass, more preferably 60% by mass, still more preferably 70% by mass, and particularly preferably 80% by mass.

The polymer (A) can be synthesized by, for example, polymerizing a monomer that gives each structural unit according to a well-known procedure.

(B) Acid Generating Agent

The acid generating agent (B) is a substance that generates an acid upon exposure. The exposure light may be exemplified by types of exposure light similar to those exemplified as the exposure light in the exposing step of the method of forming a resist pattern of the other embodiment of the present invention, described later, and the like. The acid thus generated upon exposure allows the acid-labile group included in the polymer (A) or the like to be dissociated, thereby generating a carboxy group, a hydroxy group, etc., whereby a difference in solubility of the resist film in the developer solution is generated between the light-exposed regions and the light-unexposed regions, and thus formation of the resist pattern is enabled.

Examples of the acid generated from the acid generating agent (B) include sulfonic acid, imidic acid, and the like.

The acid generating agent (B) is exemplified by an onium salt compound, an N-sulfonyloxyimide compound, a sulfonimide compound, a halogen-containing compound, a diazoketone compound, and the like.

Examples of the onium salt compound include sulfonium salts, tetrahydrothiophenium salts, iodonium salts, phosphonium salts, diazonium salts, pyridinium salts, and the like.

Specific examples of the acid generating agent (B) include compounds disclosed in paragraphs [0080] to [0113] of Japanese Unexamined Patent Application, Publication No. 2009-134088, and the like.

Examples of the acid generating agent (B) which generates sulfonic acid upon exposure include a compound (hereinafter, may be also referred to as “(B) compound” or “compound (B)”) represented by the following formula (4), and the like. It is to be noted that herein below, a monovalent radiation-sensitive onium cation represented by T⁺ in the following formula (4) is referred to as an “onium cation”, and a moiety other than the onium cation is referred to as an “anion”.

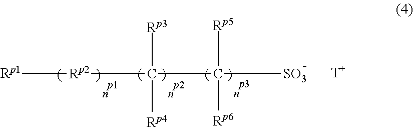

In the above formula (4), R^{p1} represents a monovalent group including a ring structure having 5 or more ring atoms; R^{p2} represents a divalent linking group; R^{p3} and R^{p4} each independently represent a hydrogen atom, a fluorine atom, a monovalent hydrocarbon group having 1 to 20 carbon atoms, or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10, n^{p2} is an integer of 0 to 10, and n^{p3} is an integer of 0 to 10, wherein the sum of n^{p1}, n^{p2} and n^{p3} is no less than 1 and no greater than 30, and wherein in a case in which n^{p1} is no less than 2, a plurality of R^{p2}s are identical or different from each other, in a case in which n^{p2} is no less than 2, a plurality of R^{p3}s are identical or different from each other and a plurality of R^{p4}s are identical or different from each other, and in a case in which n^{p3} is no less than 2, a plurality of R^{p5}s are identical or different from each other and a plurality of R^{p6}s are identical or different from each other; and T⁺ represents a monovalent radiation-sensitive onium cation.

The monovalent group including a ring structure having 5 or more ring atoms which is represented by R^{p1} is exemplified by: a monovalent group including an alicyclic structure having 5 or more ring atoms; a monovalent group including an aliphatic heterocyclic structure having 5 or more ring atoms; a monovalent group including an aromatic carbocyclic structure having 6 or more ring atoms; a monovalent group including an aromatic heterocyclic structure having 5 or more ring atoms; and the like.

Examples of the alicyclic structure having 5 or more ring atoms include: monocyclic saturated alicyclic structures such as a cyclopentane structure, a cyclohexane structure, a cycloheptane structure, a cyclooctane structure, a cyclononane structure, a cyclodecane structure, and a cyclododecane structure; monocyclic unsaturated alicyclic structures such as a cyclopentene structure, a cyclohexene structure, a cycloheptene structure, a cyclooctene structure, and a cyclodecene structure; polycyclic saturated alicyclic structures such as a norbornane structure, an adamantane structure, a tricyclodecane structure, and a tetracyclododecane structure; polycyclic unsaturated alicyclic structures such as a norbornene structure and a tricyclodecene structure; and the like.

Examples of the aliphatic heterocyclic structure having 5 or more ring atoms include: lactone structures such as a hexanolactone structure and a norbornanelactone structure; sultone structures such as a hexanosultone structure and a norbornanesultone structure; oxygen atom-containing heterocyclic structures such as an oxacycloheptane structure and an oxanorbornane structure; nitrogen atom-containing heterocyclic structures such as an azacyclohexane structure and a diazabicyclooctane structure; sulfur atom-containing heterocyclic structures such as a thiacyclohexane structure and a thianorbornane structure; and the like.

Examples of the aromatic carbocyclic structure having 6 or more ring atoms include a benzene structure, a naphthalene structure, a phenanthrene structure, an anthracene structure, and the like.

Examples of the aromatic heterocyclic structure having 5 or more ring atoms include: oxygen atom-containing heterocyclic structures such as a furan structure, a pyran structure, a benzofuran structure, and a benzopyran structure; nitrogen atom-containing heterocyclic structures such as a pyridine structure, a pyrimidine structure, and an indole structure; and the like.

The lower limit of the number of ring atoms in the ring structure in R^{p1} is preferably 6, more preferably 8, still more preferably 9, and particularly preferably 10. The upper limit of the number of ring atoms is preferably 15, more preferably 14, still more preferably 13, and particularly preferably 12. When the number of ring atoms falls within the above range, the diffusion length of the acid can be further properly decreased, and as a result, the sensitivity to exposure light as well as the LWR performance of the resist pattern formed from the radiation-sensitive resin composition can be further improved, whereby a process window can be further expanded.

A part or all of hydrogen atoms included in the ring structure of R^{p1} may be substituted with a substituent. Examples of the substituent include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, a hydroxy group, a fluorine atom, or an iodine atom is preferred.

R^{p1} represents preferably a monovalent group including an alicyclic structure having 5 or more ring atoms, a monovalent group including an aromatic carbocyclic structure having 6 or more ring atoms, or a monovalent group including an aliphatic heterocyclic structure having 5 or more ring atoms, and more preferably a monovalent group including a polycyclic saturated alicyclic structure having 5 or more ring atoms, a monovalent group including an iodine atom-containing aromatic carbocyclic structure having 6 or more ring atoms, a monovalent group including an oxygen atom-containing heterocyclic structure having 5 or more ring atoms, or a monovalent group including a sulfur atom-containing heterocyclic structure having 5 or more ring atoms.

Examples of the divalent linking group represented by R^{p2} include a carbonyl group, an ether group, a carbonyloxy group, a sulfide group, a thiocarbonyl group, a sulfonyl group, a divalent hydrocarbon group, and the like. Of these, the carbonyloxy group, the sulfonyl group, an alkanediyl group, or a divalent alicyclic saturated hydrocarbon group is preferred, and the carbonyloxy group is more preferred.

The monovalent hydrocarbon group having 1 to 20 carbon atoms which may be represented by each of R^{p3} and R^{p4} is exemplified by an alkyl group having 1 to 20 carbon atoms, and the like. The monovalent fluorinated hydrocarbon group having 1 to 20 carbon atoms which may be represented by each of R^{p3} and R^{p4} is exemplified by a fluorinated alkyl group having 1 to 20 carbon atoms, and the like. R^{p3} and R^{p4} each independently represent preferably a hydrogen atom, a fluorine atom, or a fluorinated alkyl group, more preferably a hydrogen atom, a fluorine atom, or a perfluoroalkyl group, and still more preferably a hydrogen atom, a fluorine atom, or a trifluoromethyl group.

The monovalent fluorinated hydrocarbon group having 1 to 20 carbon atoms which may be represented by each of R^{p5} and R^{p6} is exemplified by a fluorinated alkyl group having 1 to 20 carbon atoms, and the like. R^{p5} and R^{p6} each independently represent preferably a fluorine atom or a fluorinated alkyl group, more preferably a fluorine atom or a perfluoroalkyl group, still more preferably a fluorine atom or a trifluoromethyl group, and particularly preferably a fluorine atom.

n^{p1} is preferably 0 to 5, more preferably 0 to 2, and still more preferably 0 or 1.

n^{p2} is preferably 0 to 5, more preferably 0 to 2, and still more preferably 0 or 1.

The lower limit of n^{p3} is preferably 1, and more preferably 2. When n^{p3} is no less than 1, strength of the acid can be enhanced. The upper limit of n^{p3} is preferably 4, more preferably 3, and still more preferably 2.

The lower limit of a sum of n^{p1}, n^{p2}, and n^{p3} is preferably 2, and more preferably 4. The upper limit of the sum of n^{p1}, n^{p2}, and n^{p3} is preferably 20, and more preferably 10.

Examples of the anion include anions represented by the following formulae (4-1) to (4-13), and the like.

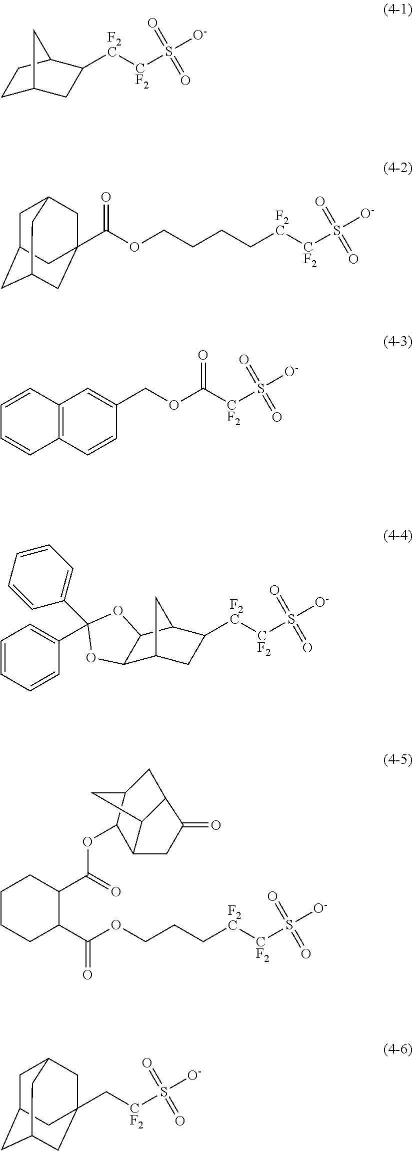 [SMILES: O=S(=O)([O-])C(F)(F)C(F)(F)C1CC2CCC1C2 ; O=C(OCCCCC(F)(F)C(F)(F)S(=O)(=O)[O-])C12CC3CC(CC(C3)C1)C2 ; O=C(OCc1ccc2ccccc2c1)C(F)(F)S(=O)(=O)[O-] ; O=S(=O)([O-])C(F)(F)C(F)(F)C1CC2CC1C1OC(c3ccccc3)(c3ccccc3)OC21 ; O=C(OCCCC(F)(F)C(F)(F)S(=O)(=O)[O-])C1CCCCC1C(=O)OC1C2CC3C(=O)CC1C3C2 ; O=S(=O)([O-])C(F)(F)CC12CC3CC(CC(C3)C1)C2]

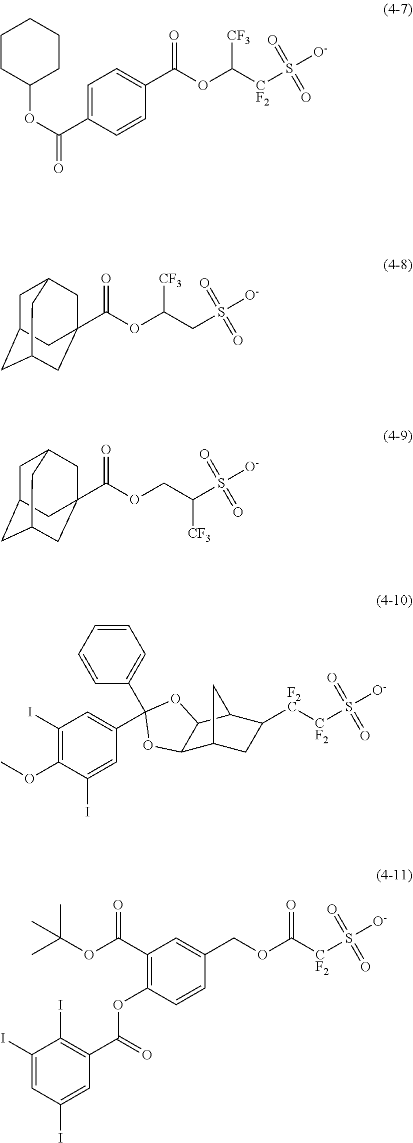 [SMILES: O=C(OC1CCCCC1)c1ccc(C(=O)OC(C(F)(F)F)C(F)(F)S(=O)(=O)[O-])cc1 ; O=C(OC(CS(=O)(=O)[O-])C(F)(F)F)C12CC3CC(CC(C3)C1)C2 ; O=C(OCC(C(F)(F)F)S(=O)(=O)[O-])C12CC3CC(CC(C3)C1)C2 ; COc1c(I)cc(C2(c3ccccc3)OC3C4CC(C3O2)C(C(F)(F)C(F)(F)S(=O)(=O)[O-])C4)cc1I ; CC(C)(C)OC(=O)c1cc(COC(=O)C(F)(F)S(=O)(=O)[O-])ccc1OC(=O)c1cc(I)cc(I)c1I]

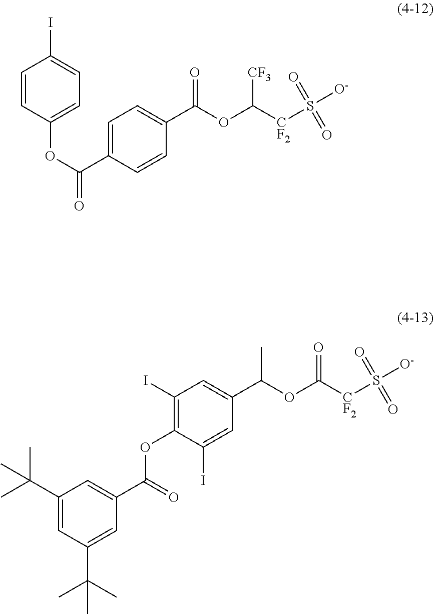 [SMILES: O=C(Oc1ccc(I)cc1)c1ccc(C(=O)OC(C(F)(F)F)C(F)(F)S(=O)(=O)[O-])cc1 ; CC(OC(=O)C(F)(F)S(=O)(=O)[O-])c1cc(I)c(OC(=O)c2cc(C(C)(C)C)cc(C(C)(C)C)c2)c(I)c1]

Examples of the monovalent radiation-sensitive onium cation represented by T⁺ include monovalent cations (hereinafter, may be also referred to as “cations (r-a) to (r-c)”) represented by the following formulae (r-a) to (r-c), and the like.

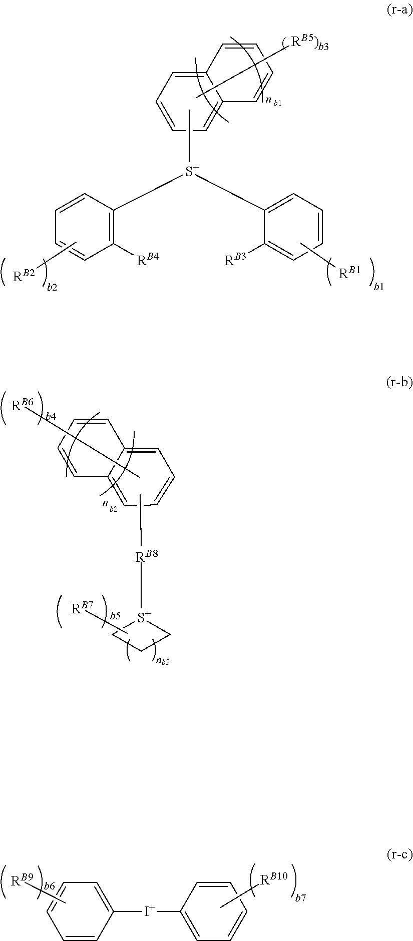

In the above formula (r-a), b1 is an integer of 0 to 4, wherein in a case in which b1 is 1, R^{B1} represents a halogen atom, a hydroxy group, a nitro group, or a monovalent organic group having 1 to 20 carbon atoms, and in a case in which b1 is no less than 2, a plurality of R^{B1}s are identical or different from each other, and each R^{B1} represents a halogen atom, a hydroxy group, a nitro group, or a monovalent organic group having 1 to 20 carbon atoms, or the plurality of R^{B1}s taken together represent a ring structure having 4 to 20 ring atoms together with the carbon chain to which the plurality of R^{B1}s bond; b2 is an integer of 0 to 4, wherein in a case in which b2 is 1, R^{B2} represents a halogen atom, a hydroxy group, a nitro group, or a monovalent organic group having 1 to 20 carbon atoms, and in a case in which b2 is no less than 2, a plurality of R^{B2}s are identical or different from each other, and each R^{B2} represents a halogen atom, a hydroxy group, a nitro group, or a monovalent organic group having 1 to 20 carbon atoms, or the plurality of R^{B2}s taken together represent a ring structure having 4 to 20 ring atoms together with the carbon chain to which the plurality of R^{B2}s bond; R^{B3} and R^{B4} each independently represent a hydrogen atom, a halogen atom, a hydroxy group, a nitro group, or a monovalent organic group having 1 to 20 carbon atoms, or R^{B3} and R^{B4} taken together represent a single bond; b3 is an integer of 0 to 11, wherein in a case in which b3 is 1, R^{B5} represents a halogen atom, a hydroxy group, a nitro group, or a monovalent organic group having 1 to 20 carbon atoms, and in a case in which b3 is no less than 2, a plurality of R^{B5}s are identical or different from each other, and each R^{B5} represents a halogen atom, a hydroxy group, a nitro group, or a monovalent organic group having 1 to 20 carbon atoms, or the plurality of R^{B5}s taken together represent a ring structure having 4 to 20 ring atoms together with the carbon chain to which the plurality of R^{B5}s bond; and n_{b1} is an integer of 0 to 3.

In the above formula (r-b), b4 is an integer of 0 to 9, wherein in a case in which b4 is 1, R^{B6} represents a halogen atom, a hydroxy group, a nitro group, or a monovalent organic group having 1 to 20 carbon atoms, and in a case in which b4 is no less than 2, a plurality of R^{B6}s are identical or different from each other, and each R^{B6} represents a halogen atom, a hydroxy group, a nitro group, or a monovalent organic group having 1 to 20 carbon atoms, or the plurality of R^{B6}s taken together represent a ring structure having 4 to 20 ring atoms together with the carbon chain to which the plurality of R^{B6}s groups bond; b5 is an integer of 0 to 10, wherein in a case in which b5 is 1, R^{B7} represents a halogen atom, a hydroxy group, a nitro group, or a monovalent organic group having 1 to 20 carbon atoms, and in a case in which b5 is no less than 2, a plurality of R^{B7}s are identical or different from each other, and each R^{B7} represents a halogen atom, a hydroxy group, a nitro group, or a monovalent organic group having 1 to 20 carbon atoms, or the plurality of R^{B7}s taken together represent a ring structure having 3 to 20 ring atoms together with the carbon atom or the carbon chain to which the plurality of R^{B7}s bond; n_{b3} is an integer of 0 to 3; R^{B8} is a single bond or a divalent organic group having 1 to 20 carbon atoms; and n_{b2} is an integer of 0 to 2.

In the above formula (r-c), b6 is an integer of 0 to 5, wherein in a case in which b6 is 1, R^{B9} represents a halogen atom, a hydroxy group, a nitro group, or a monovalent organic group having 1 to 20 carbon atoms, and in a case in which b6 is no less than 2, a plurality of R^{B9}s are identical or different from each other, and each R^{B9} represents a halogen atom, a hydroxy group, a nitro group, or a monovalent organic group having 1 to 20 carbon atoms, or the plurality of R^{B9}s taken together represent a ring structure having 4 to 20 ring atoms together with the carbon chain to which the plurality of R^{B9}s bond; and b7 is an integer of 0 to 5, wherein in a case in which b7 is 1, R^{B10} represents a halogen atom, a hydroxy group, a nitro group, or a monovalent organic group having 1 to 20 carbon atoms, and in a case in which b7 is no less than 2, a plurality of R^{B10}s are identical or different from each other, and each R^{B10} represents a halogen atom, a hydroxy group, a nitro group, or a monovalent organic group having 1 to 20 carbon atoms, or these groups taken together represent a ring structure having 4 to 20 ring atoms together with the carbon chain to which the plurality of R^{B10}s bond.

Examples of the monovalent organic group having 1 to 20 carbon atoms which may be represented by R^{B1}, R^{B2}, R^{B3}, R^{B4}, R^{B5}, R^{B6}, R^{B7}, R^{B9}, or R^{B10} include groups similar to the groups exemplified as the monovalent organic group which may be represented by R² or R³ in the above formula (1), and the like.

Examples of the divalent organic group which may be represented by R^{B8} include groups obtained by removing one hydrogen atom from the groups exemplified as the monovalent organic group which may be represented by R² or R³ in the above formula (1), and the like.

R^{B3} and R^{B4} preferably each represent a hydrogen atom, or taken together represent a single bond.

b1 and b2 are each preferably 0 to 2, more preferably 0 or 1, and still more preferably 0. b3 is preferably 0 to 4, more preferably 0 to 2, and still more preferably 0 or 1. n_{b1} is preferably 0 or 1.

In the case in which b3 is no less than 1, R^{B5} is preferably a cyclohexyl group or a cyclohexylsulfonyl group.

Examples of the onium cation include cations represented by the following formulae (r-a-1) to (r-a-9), (r-b-1) and (r-c-1), and the like.

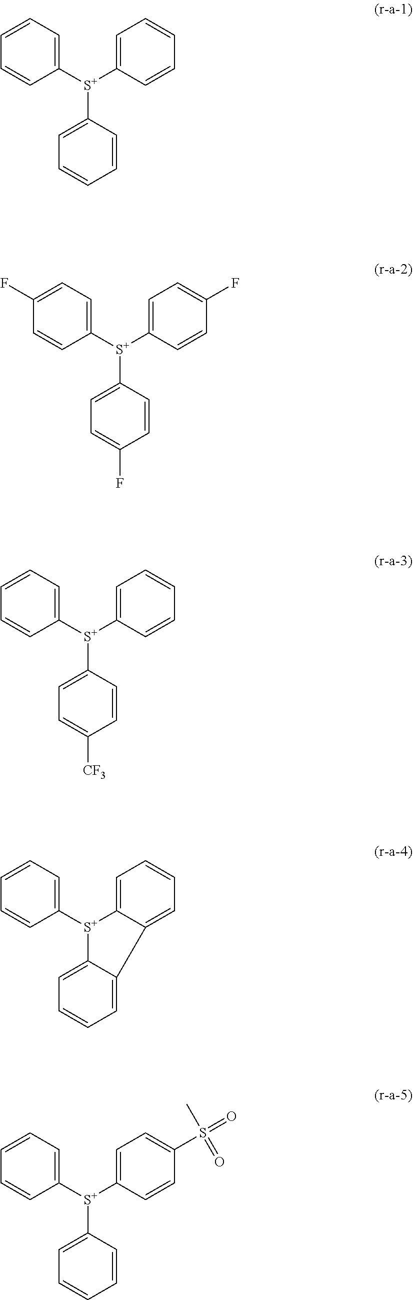 [SMILES: c1ccc([S+](c2ccccc2)c2ccccc2)cc1 ; Fc1ccc([S+](c2ccc(F)cc2)c2ccc(F)cc2)cc1 ; FC(F)(F)c1ccc([S+](c2ccccc2)c2ccccc2)cc1 ; c1ccc(-[s+]2c3ccccc3c3ccccc32)cc1 ; CS(=O)(=O)c1ccc([S+](c2ccccc2)c2ccccc2)cc1]

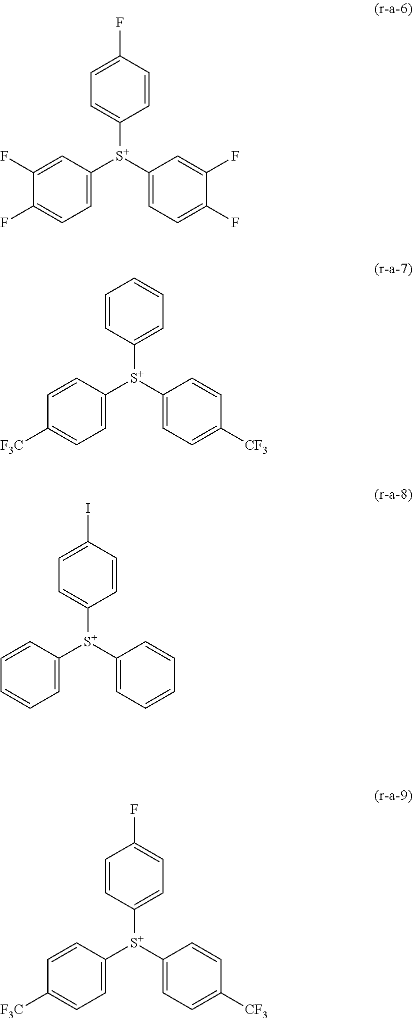 [SMILES: Fc1ccc([S+](c2ccc(F)c(F)c2)c2ccc(F)c(F)c2)cc1 ; FC(F)(F)c1ccc([S+](c2ccccc2)c2ccc(C(F)(F)F)cc2)cc1 ; Ic1ccc([S+](c2ccccc2)c2ccccc2)cc1 ; Fc1ccc([S+](c2ccc(C(F)(F)F)cc2)c2ccc(C(F)(F)F)cc2)cc1]

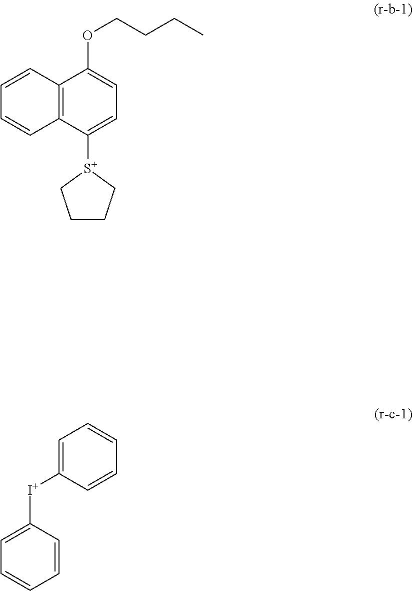 [SMILES: CCCCOc1ccc([S+]2CCCC2)c2ccccc12 ; c1ccc([I+]c2ccccc2)cc1]

As the acid generating agent (B), a compound in which the onium cation exemplified above is combined with the anion exemplified above can be used.

The lower limit of a content of the acid generating agent (B) in the radiation-sensitive resin composition with respect to 100 parts by mass of the polymer (A) is preferably 1 part by mass, more preferably 5 parts by mass, and still more preferably 10 parts by mass. The upper limit of the content is preferably 80 parts by mass, more preferably 70 parts by mass, and still more preferably 60 parts by mass. When the content of the acid generating agent (B) falls within the above range, the sensitivity to exposure light, as well as the LWR performance and the CDU performance of the resist pattern formed from the radiation-sensitive resin composition can be further improved.

(C) Acid Diffusion Control Agent

The acid diffusion control agent (C) is able to control a diffusion phenomenon, in the resist film, of the acid generated from the acid generating agent (B), etc. upon exposure, thereby serving to inhibit unwanted chemical reactions in light-unexposed regions. When the radiation-sensitive resin composition contains the acid diffusion control agent (C), the sensitivity to exposure light, the LWR performance, and the CDU performance resulting from the radiation-sensitive resin composition can be further improved. The radiation-sensitive resin composition may contain one, or two or more types of the acid diffusion control agent (C).

The acid diffusion control agent (C) is exemplified by a nitrogen atom-containing compound, a photodegradable base that is photosensitized by exposure to generate a weak acid, and the like.

Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N-(undecylcarbonyloxyethyl)morpholine, and N-t-pentyloxycarbonyl-4-hydroxypiperidine; and the like.

The photodegradable base is exemplified by a compound containing an onium cation degraded by exposure, and an anion of a weak acid; and the like. In a light-exposed region, the photodegradable base generates a weak acid from: a proton produced upon degradation of the onium cation; and the anion of the weak acid, whereby acid diffusion controllability decreases.

Examples of the onium cation degraded by exposure include cations represented by the above formulae (r-a) to (r-c). Of these, a triphenylsulfonium cation (cation (r-a-1)), a phenyldibenzothiophenium cation (cation (r-a-4)), a diphenyl(4-(cyclohexylsulfonyl)phenyl)sulfonium cation, a tris(4-fluorophenyl)sulfonium cation (cation (r-a-2)), or a diphenyl(4-trifluoromethylphenyl)sulfonium cation (cation (r-a-3)) is preferred.

Examples of the anion of the weak acid include anions represented by the following formulae, and the like.

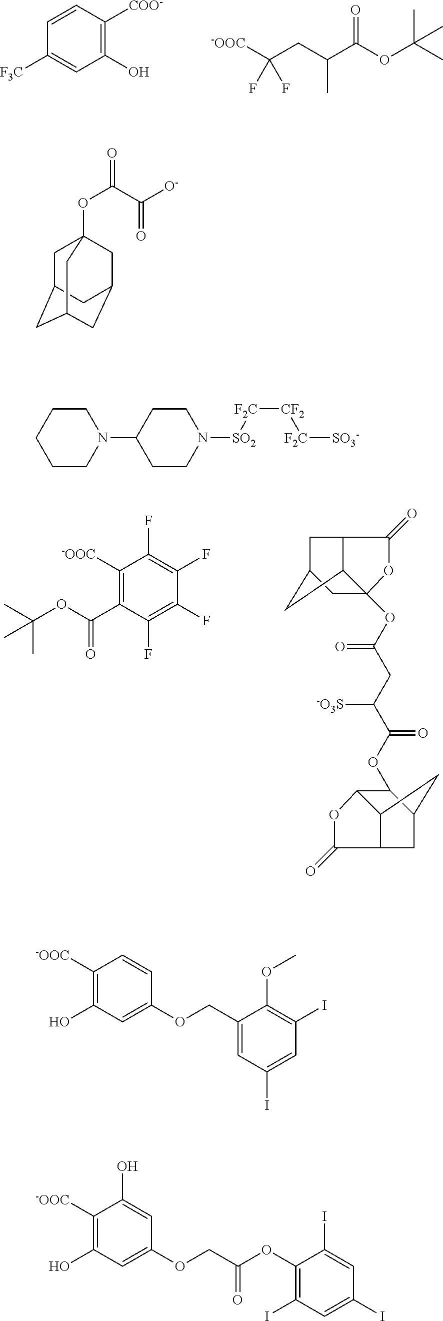

As the photodegradable base, a compound in which the onium cation degraded by exposure and the anion of a weak acid are appropriately combined can be used.

In the case of the radiation-sensitive resin composition containing the acid diffusion control agent (C), the lower limit of a content of the acid diffusion control agent (C) with respect to 100 parts by mass of the polymer (A) is preferably 0.5 parts by mass, more preferably 1 part by mass, still more preferably 5 parts by mass, and even further preferably 10 parts by mass. The upper limit of the content is preferably 45 parts by mass, more preferably 40 parts by mass, still more preferably 35 parts by mass, and even further preferably 30 parts by mass. When the content of the acid diffusion control agent (C) falls within the above range, the sensitivity to exposure light, as well as the LWR performance and the CDU performance of the resist pattern formed from the radiation-sensitive resin composition can be further improved.

(D) Organic Solvent

The radiation-sensitive resin composition typically contains the organic solvent (D). The organic solvent (D) is not particularly limited as long as it is a solvent capable of dissolving or dispersing at least the polymer (A) and the acid generating agent (B), as well as the acid diffusion control agent (C), the polymer (E), and the other optional component(s), and the like, which is/are contained as needed.

The organic solvent (D) is exemplified by an alcohol solvent, an ether solvent, a ketone solvent, an amide solvent, an ester solvent, a hydrocarbon solvent, and the like. The radiation-sensitive resin composition may contain one, or two or more types of the organic solvent (D).

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol 1-monomethyl ether; and the like.

Examples of the ether solvent include:

dialkyl ether solvents such as diethyl ether, dipropyl ether, dibutyl ether, dipentyl ether, diisoamyl ether, dihexyl ether, and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone;

cyclic ketone solvents such as cyclopentanone, cyclohexanone, cycloheptanone, cyclooctanone, and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:

monocarboxylic acid ester solvents such as n-butyl acetate and ethyl lactate;

lactone solvents such as γ-butyrolactone and valerolactone;

polyhydric alcohol carboxylate solvents such as propylene glycol acetate; polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

The organic solvent (D) is preferably the alcohol solvent, the ester solvent, or a combination of these, more preferably the polyhydric alcohol partial ether solvent having 3 to 19 carbon atoms, the monocarboxylic acid ester solvent, the lactone solvent, the polyhydric alcohol partial ether carboxylate solvent, or a combination of these, and still more preferably propylene glycol 1-monomethyl ether, ethyl lactate, 7-butyrolactone, propylene acetate glycol 1-monomethyl ether, or a combination of these.

In the case of the radiation-sensitive resin composition containing the organic solvent (D), the lower limit of a proportion of the organic solvent (D) with respect to total components contained in the radiation-sensitive resin composition is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

(E) Polymer

The polymer (E) is a polymer having a percentage content by mass of fluorine atoms greater than that of the polymer (A). In general, a polymer being more hydrophobic than the polymer which is to be a base polymer tends to be localized in a surface layer of the resist film. Since the polymer (E) has a percentage content by mass of fluorine atoms greater than that of the polymer (A), the polymer (E) tends to be localized in a surface layer of the resist film due to the characteristic resulting from the hydrophobicity. As a result, in the case in which the radiation-sensitive resin composition contains the polymer (E), elution of the acid generating agent, the acid diffusion control agent, and the like into a liquid immersion medium can be inhibited during the liquid immersion lithography. In addition, in the case in which the radiation-sensitive resin composition contains the polymer (E), an advancing contact angle of a liquid immersion medium on the resist film can be adjusted to fall within a desired range owing to the hydrophobicity that results from the characteristics of the polymer (E), thereby enabling generation of the bubble defects to be inhibited. Furthermore, the radiation-sensitive resin composition leads to an increase in a receding contact angle of the liquid immersion medium on the resist film, whereby a scanning exposure at a high speed without being accompanied by residual water droplets is enabled. Due to further containing the polymer (E) in this manner, the radiation-sensitive resin composition is capable of forming a resist film suited for a liquid immersion lithography process. Furthermore, due to containing the polymer (E), the radiation-sensitive resin composition can form a resist pattern with generation of defects being inhibited.

The lower limit of a percentage content by mass of fluorine atoms in the polymer (E) is preferably 1% by mass, more preferably 2% by mass, and still more preferably 3% by mass. The upper limit of the percentage content by mass is preferably 60% by mass, more preferably 50% by mass, and still more preferably 40% by mass. When the percentage content by mass of fluorine atoms falls within the above range, localization of the polymer (E) in the resist film can be more adequately adjusted. It is to be noted that the percentage content by mass of fluorine atoms in the polymer may be calculated based on the structure of the polymer determined by ¹³C-NMR spectroscopy.

The mode of incorporation of the fluorine atom in the polymer (E) is not particularly limited, and the fluorine atom may be bonded to either the main chain or the side chain of the polymer (E). In a preferred mode of incorporation of the fluorine atom in the polymer (E), the polymer (E) has a structural unit (hereinafter, may be also referred to as “structural unit (I′)”) including a fluorine atom. The polymer (E) may further have a structural unit aside from the structural unit (I′). The polymer (E) may have one, or two or more types of each structural unit. The radiation-sensitive resin composition may contain one, or two or more types of the polymer (E).

Each structural unit contained in the polymer (E) is described below.

Structural unit (I′)

The structural unit (I′) is a structural unit including a fluorine atom. Examples of the structural unit (I′) include a structural unit (hereinafter, may be also referred to as “structural unit (I′-1)”) represented by the following formula (f), and the like.

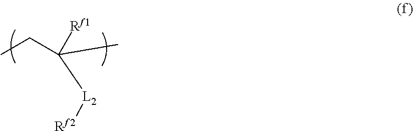

In the above formula (f), R^{f1} represents a hydrogen atom, a fluorine atom, a methyl group, or a trifluoromethyl group; L² represents a single bond, an oxygen atom, a sulfur atom, —COO—, —SO₂ONH—, —CONH—, or —OCONH—; and R² represents a monovalent organic group having 1 to 10 carbon atoms including a fluorine atom.

In light of the copolymerizability of a monomer that gives the structural unit (I′-1), R^{f1} represents preferably a hydrogen atom or a methyl group, and more preferably a methyl group.

L² represents preferably —COO—.

Examples of the monovalent organic group having 1 to 10 carbon atoms including a fluorine atom represented by R² include groups similar to those exemplified as the monovalent organic group having 1 to 20 carbon atoms which may be represented by R¹, R² or R³ in the above formula (1), and the like.

R² represents preferably a fluorinated chain hydrocarbon group or a group obtained by substituting with a hydroxy group, a part or all of hydrogen atoms of the fluorinated chain hydrocarbon group.

The structural unit (I′-1) is preferably one of structural units represented by the following formulae.

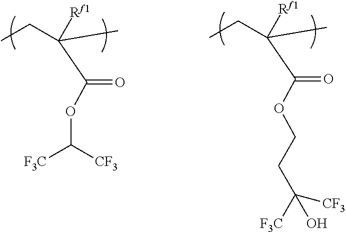

In the above formulae, R^{f1} is as defined in the above formula (f).

In the case in which the polymer (E) has the structural unit (I′), the lower limit of a proportion of the structural unit (I′) with respect to the total structural units constituting the polymer (E) is preferably 20 mol %, more preferably 30 mol %, and still more preferably 40 mol %. The upper limit of the proportion is preferably 90 mol %, more preferably 80 mol %, and still more preferably 70 mol %. When the proportion of the structural unit (F) falls within the above range, the percentage content by mass of the fluorine atoms in the polymer (E) can be more properly adjusted.

Other Structural Unit

Examples of the other structural unit include a structural unit (hereinafter, may be also referred to as “structural unit (II′)”) having an acid-labile group, and the like. Examples of the structural unit (II′) include structural units similar to those exemplified as the structural unit (II) of the polymer (A), and the like.

In the case in which the polymer (E) has the structural unit (II′), the lower limit of a proportion of the structural unit (II′) with respect to the total structural units constituting the polymer (E) is preferably 10 mol %, more preferably 20 mol %, and still more preferably 30 mol %. The upper limit of the proportion is preferably 80 mol %, more preferably 70 mol %, and still more preferably 60 mol %.

The lower limit of the Mw of the polymer (E) as determined by GPC is preferably 1,000, more preferably 2,000, still more preferably 3,000, and particularly preferably 4,000. The upper limit of the Mw is preferably 50,000, more preferably 20,000, still more preferably 10,000, and particularly preferably 8,000.

The upper limit of the ratio (Mw/Mn) of the Mw to the Mn of the polymer (E) as determined by GPC is preferably 5.00, more preferably 3.00, still more preferably 2.50, and particularly preferably 2.00. The lower limit of the ratio is typically 1.00, and preferably 1.20.

The polymer (E) can be synthesized similarly to the polymer (A), for example, by polymerizing a monomer that gives each structural unit according to a well-known procedure.

In the case in which the radiation-sensitive resin composition contains the polymer (E), the lower limit of a content of the polymer (E) with respect to 100 parts by mass of the polymer (A) is preferably 0.5 parts by mass, more preferably 1 part by mass, and still more preferably 2 parts by mass. The upper limit of the content is preferably 20 parts by mass, more preferably 15 parts by mass, and still more preferably 10 parts by mass.

Other Optional Component(s)

The other optional component(s) is/are exemplified by a surfactant and the like. The radiation-sensitive resin composition may contain one, or two or more types each of the other optional component(s).

Method of Preparing Radiation-Sensitive Resin Composition

The radiation-sensitive resin composition may be prepared, for example, by: mixing the polymer (A) and the acid generating agent (B), as well the acid diffusion control agent (C), the organic solvent (D), the polymer (E), and the other optional component(s), and the like, which are added as needed, in a certain ratio; and preferably filtering a thus resulting mixture through a membrane filter having a pore size of no greater than 0.2 m.

### Method of Forming Resist Pattern

The method of forming a resist pattern according to another embodiment of the present invention includes: a step (hereinafter, may be also referred to as “applying step”) of applying a radiation-sensitive resin composition directly or indirectly on a substrate; a step (hereinafter, may be also referred to as “exposing step”) of exposing a resist film formed by the applying step; and a step (hereinafter, may be also referred to as “developing step”) of developing the resist film exposed. In the method of forming a resist pattern, the radiation-sensitive resin composition of the one embodiment of the present invention is used as the radiation-sensitive resin composition.

According to the method of forming a resist film, due to using the radiation-sensitive resin composition of the one embodiment of the present invention as the radiation-sensitive resin composition in the applying step, formation of a resist pattern with favorable sensitivity to exposure light and superiority in terms of the LWR performance and the CDU performance is enabled.

Each step included in the method of forming a resist pattern will be described below.

Applying Step

In this step, the radiation-sensitive resin composition is applied directly or indirectly on the substrate. By this step, the resist pattern is formed directly or indirectly on the substrate.

In this step, the radiation-sensitive resin composition of the one embodiment of the present invention, described above, is used as the radiation-sensitive resin composition.

The substrate is exemplified by a conventionally well-known substrate such as a silicon wafer, a wafer coated with silicon dioxide or aluminum, and the like. In addition, the case of the radiation-sensitive resin composition being applied indirectly on the substrate is exemplified by a case of the radiation-sensitive resin composition being applied on an antireflective film formed on the substrate, and the like. Examples of such an antireflective film include an organic or inorganic antireflective film disclosed in Japanese Examined Patent Application, Publication No. H6-12452, Japanese Unexamined Patent Application, Publication No. S59-93448, and the like.

An application procedure is exemplified by spin coating, cast coating, roll coating, and the like. After the application, prebaking (hereinafter, may be also referred to as “PB”) may be carried out as needed for evaporating the solvent remaining in the coating film. The lower limit of a PB temperature is preferably 60° C., and more preferably 80° C. The upper limit of the PB temperature is preferably 150° C., and more preferably 140° C. The lower limit of a PB time period is preferably 5 seconds, and more preferably 10 seconds. The upper limit of the PB time period is preferably 600 seconds, and more preferably 300 seconds. The lower limit of an average thickness of the resist film formed is preferably 10 nm, and more preferably 20 nm. The upper limit of the average thickness is preferably 1,000 nm, and more preferably 500 nm.

Exposing Step

In this step, the resist film formed by the applying step is exposed. This exposure is carried out by irradiation with an exposure light through a photomask (as the case may be, through a liquid immersion medium such as water). Examples of the exposure light include electromagnetic waves such as visible light rays, ultraviolet rays, far ultraviolet rays, extreme ultraviolet rays (EUV), X-rays and T-rays; charged particle rays such as electron beams and α-rays; and the like, which may be selected in accordance with a line width and the like of the intended pattern. Of these, far ultraviolet rays, EUV, or electron beams are preferred; an ArF excimer laser beam (wavelength: 193 nm), a KrF excimer laser beam (wavelength: 248 nm), EUV (wavelength: 13.5 mm), or an electron beam is more preferred; and an ArF excimer laser beam, EUV, or an electron beam is still more preferred.

It is preferred that post exposure baking (hereinafter, may be also referred to as “PEB”) is carried out after the exposure to promote dissociation of the acid-labile group included in the polymer (A) and the like mediated by the acid generated from the acid generating agent (B), etc. upon the exposure in light-exposed regions of the resist film. This PEB enables an increase in a difference in solubility of the resist film in a developer solution between the light-exposed regions and light-unexposed regions. The lower limit of a PEB temperature is preferably 50° C., more preferably 80° C., and still more preferably 100° C. The upper limit of the PEB temperature is preferably 180° C., and more preferably 130° C. The lower limit of a PEB time period is preferably 5 seconds, more preferably 10 seconds, and still more preferably 30 seconds. The upper limit of the PEB time period is preferably 600 seconds, more preferably 300 seconds, and still more preferably 100 seconds.

Developing Step

In this step, the resist film exposed is developed. Accordingly, formation of a predetermined resist pattern is enabled. The development is typically followed by washing with a rinse agent such as water or an alcohol and then drying. The development procedure in the developing step may be carried out by either development with an alkali, or development with an organic solvent.

In the case of the development with an alkali, the developer solution for use in the development is exemplified by: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, and 1,5-diazabicyclo-[4.3.0]-5-nonene; and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent, and an alcohol solvent; a solution containing the organic solvent; and the like. An exemplary organic solvent includes one, or two or more types of the solvents exemplified as the organic solvent (D) of the radiation-sensitive resin composition of the one embodiment of the present invention, and the like. Of these, the ester solvent or the ketone solvent is preferred. The ester solvent is preferably an acetic acid ester solvent, and more preferably n-butyl acetate. The ketone solvent is preferably the chain ketone, and more preferably 2-heptanone. The lower limit of a content of the organic solvent in the developer solution is preferably 80% by mass, more preferably 90% by mass, still more preferably 95% by mass, and particularly preferably 99% by mass. Components other than the organic solvent in the developer solution are exemplified by water, silicone oil, and the like.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously dispensed onto the substrate, which is rotated at a constant speed, while scanning with a developer solution-dispensing nozzle at a constant speed; and the like.

The pattern to be formed according to the method of forming a resist pattern is exemplified by a line-and-space pattern, a hole pattern, and the like.

### EXAMPLES

Hereinafter, the present invention is explained in detail by way of Examples, but the present invention is not in any way limited to these Examples. Measuring methods for various types of physical property values are shown below.

Weight Average Molecular Weight (Mw), Number Average Molecular Weight (Mn), and Dispersity Index (Mw/Mn)

Measurements of the Mw and the Mn of the polymer were carried out by gel permeation chromatography (GPC) using GPC columns available from Tosoh Corporation (“G2000 HXL”×2, “G3000 HXL”×1, and “G4000 HXL”×1) under the following conditions.

elution solvent: tetrahydrofuran

flow rate: 1.0 mL/min

sample concentration: 1.0% by mass

amount of injected sample: 100 uL

column temperature: 40° C.

detector: differential refractometer

standard substance: mono-dispersed polystyrene

Proportion of Structural Unit

The proportion of each structural unit in the polymer was measured by a ¹³C-NMR analysis using a nuclear magnetic resonance apparatus (“JNM-Delta400” available from JEOL, Ltd.).

### Synthesis of Monomer (M)

As the monomer (M), compounds (hereinafter, may be also referred to as “monomer (M-1) to (M-28)”) represented by the following formulae (M-1) to (M-28) were synthesized by the following procedure.

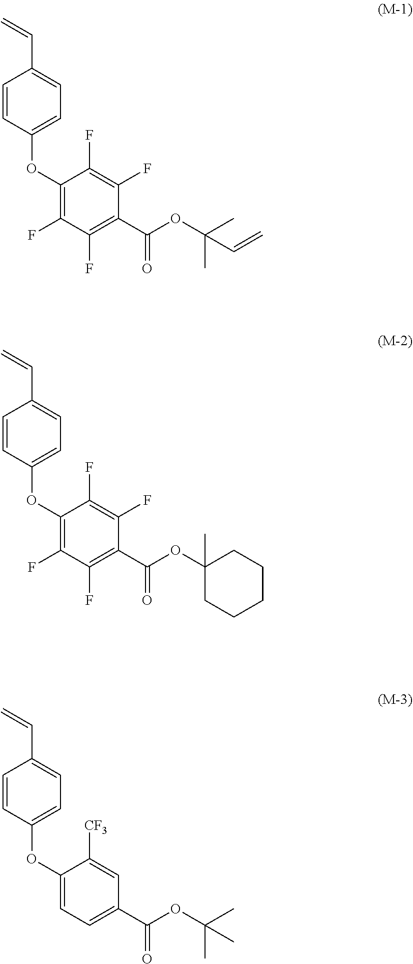 [SMILES: C=Cc1ccc(Oc2c(F)c(F)c(C(=O)OC(C)(C)C=C)c(F)c2F)cc1 ; C=Cc1ccc(Oc2c(F)c(F)c(C(=O)OC3(C)CCCCC3)c(F)c2F)cc1 ; C=Cc1ccc(Oc2ccc(C(=O)OC(C)(C)C)cc2C(F)(F)F)cc1]

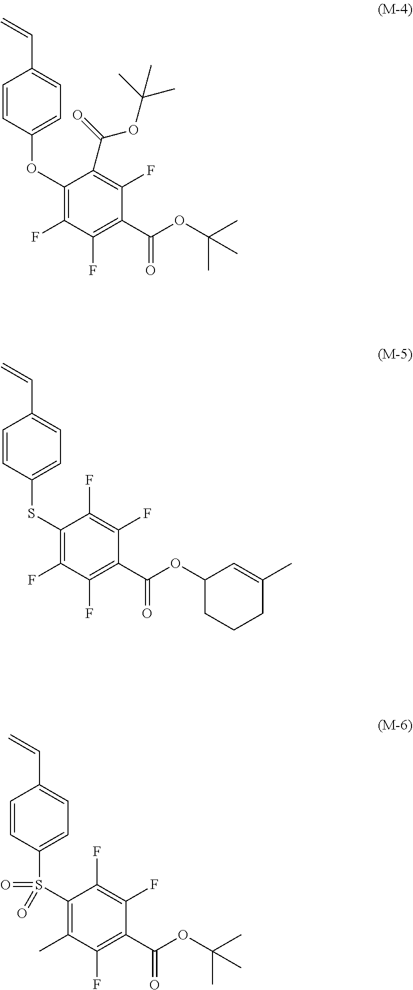 [SMILES: C=Cc1ccc(Oc2c(F)c(F)c(C(=O)OC(C)(C)C)c(F)c2C(=O)OC(C)(C)C)cc1 ; C=Cc1ccc(Sc2c(F)c(F)c(C(=O)OC3C=C(C)CCC3)c(F)c2F)cc1 ; C=Cc1ccc(S(=O)(=O)c2c(C)c(F)c(C(=O)OC(C)(C)C)c(F)c2F)cc1]

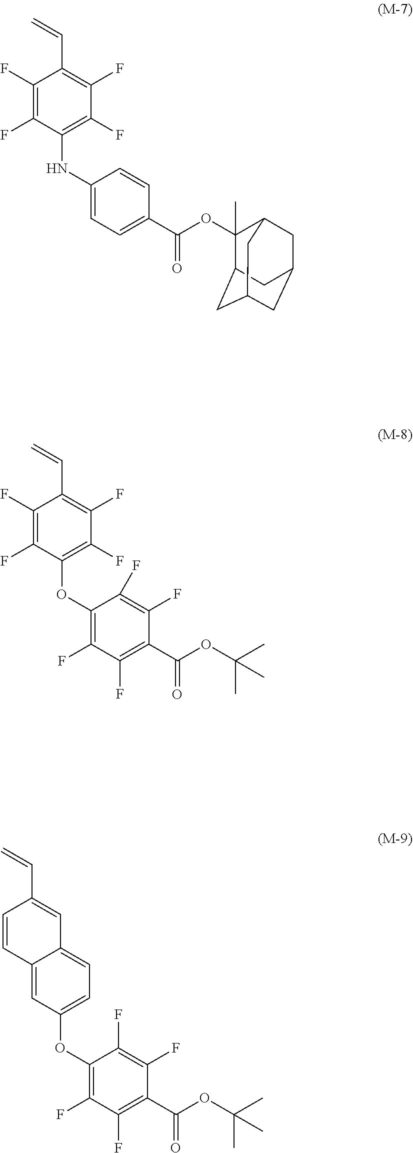 [SMILES: C=Cc1c(F)c(F)c(Nc2ccc(C(=O)OC3(C)C4CC5CC(C4)CC3C5)cc2)c(F)c1F ; C=Cc1c(F)c(F)c(Oc2c(F)c(F)c(C(=O)OC(C)(C)C)c(F)c2F)c(F)c1F ; C=Cc1ccc2cc(Oc3c(F)c(F)c(C(=O)OC(C)(C)C)c(F)c3F)ccc2c1]

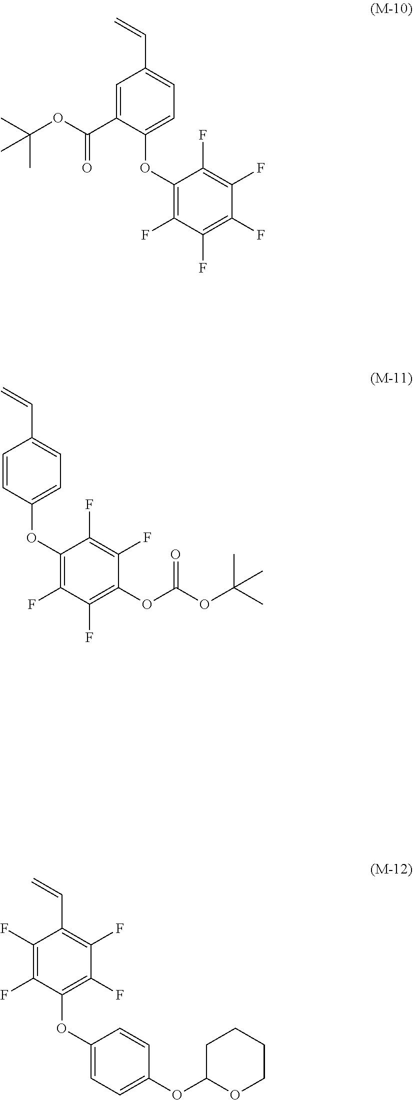 [SMILES: C=Cc1ccc(Oc2c(F)c(F)c(F)c(F)c2F)c(C(=O)OC(C)(C)C)c1 ; C=Cc1ccc(Oc2c(F)c(F)c(OC(=O)OC(C)(C)C)c(F)c2F)cc1 ; C=Cc1c(F)c(F)c(Oc2ccc(OC3CCCCO3)cc2)c(F)c1F]

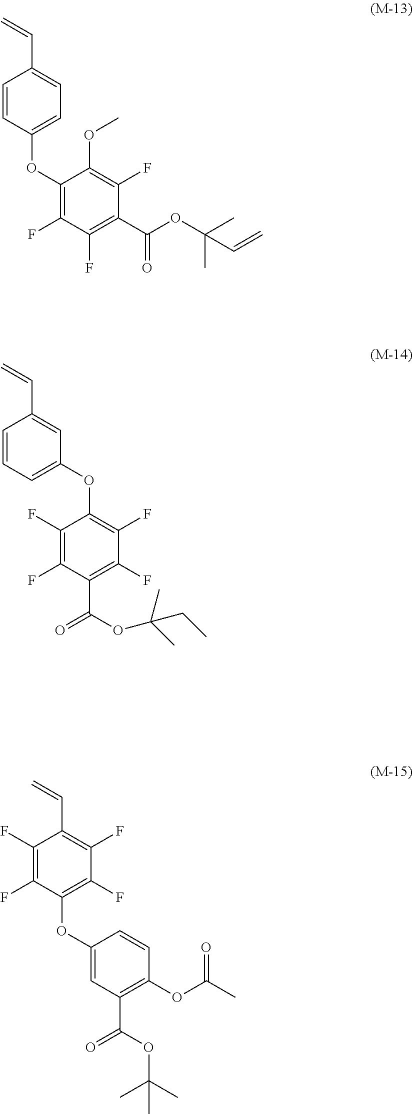 [SMILES: C=Cc1ccc(Oc2c(F)c(F)c(C(=O)OC(C)(C)C=C)c(F)c2OC)cc1 ; C=Cc1cccc(Oc2c(F)c(F)c(C(=O)OC(C)(C)CC)c(F)c2F)c1 ; C=Cc1c(F)c(F)c(Oc2ccc(OC(C)=O)c(C(=O)OC(C)(C)C)c2)c(F)c1F]

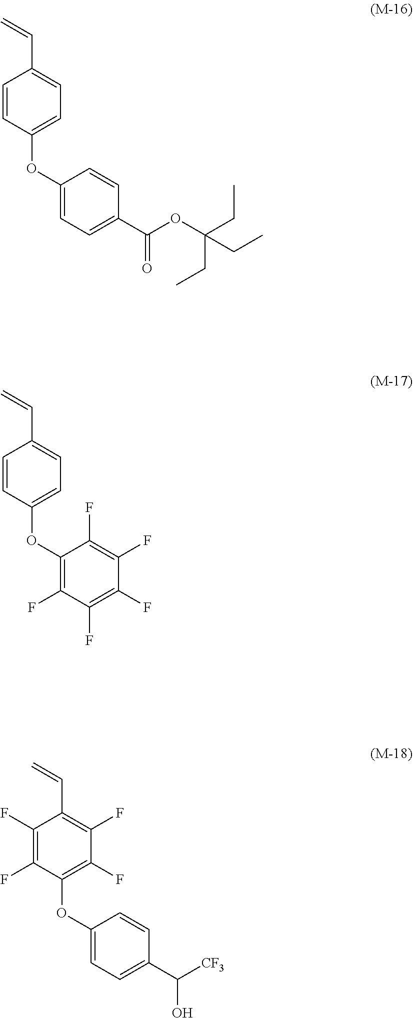 [SMILES: C=Cc1ccc(Oc2ccc(C(=O)OC(CC)(CC)CC)cc2)cc1 ; C=Cc1ccc(Oc2c(F)c(F)c(F)c(F)c2F)cc1 ; C=Cc1c(F)c(F)c(Oc2ccc(C(O)C(F)(F)F)cc2)c(F)c1F]

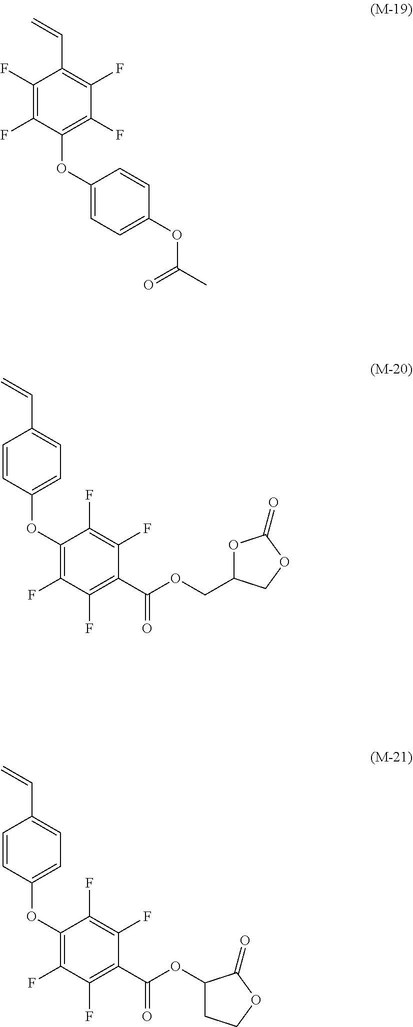 [SMILES: C=Cc1c(F)c(F)c(Oc2ccc(OC(C)=O)cc2)c(F)c1F ; C=Cc1ccc(Oc2c(F)c(F)c(C(=O)OCC3COC(=O)O3)c(F)c2F)cc1 ; C=Cc1ccc(Oc2c(F)c(F)c(C(=O)OC3CCOC3=O)c(F)c2F)cc1]

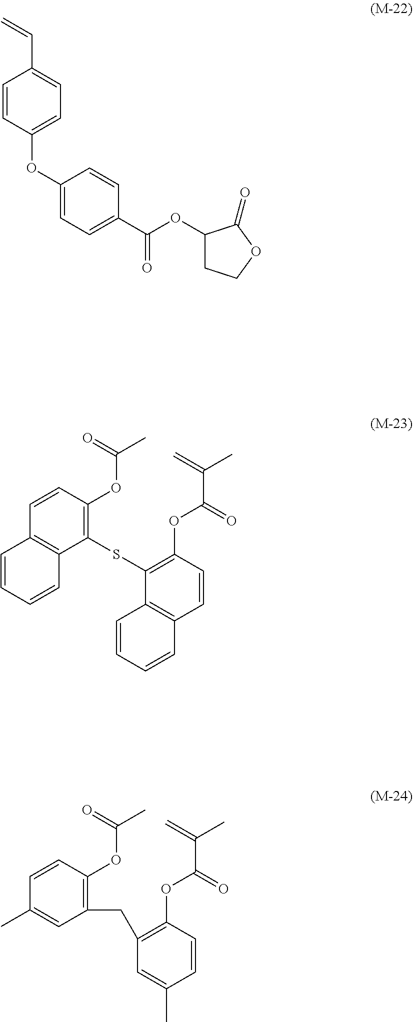

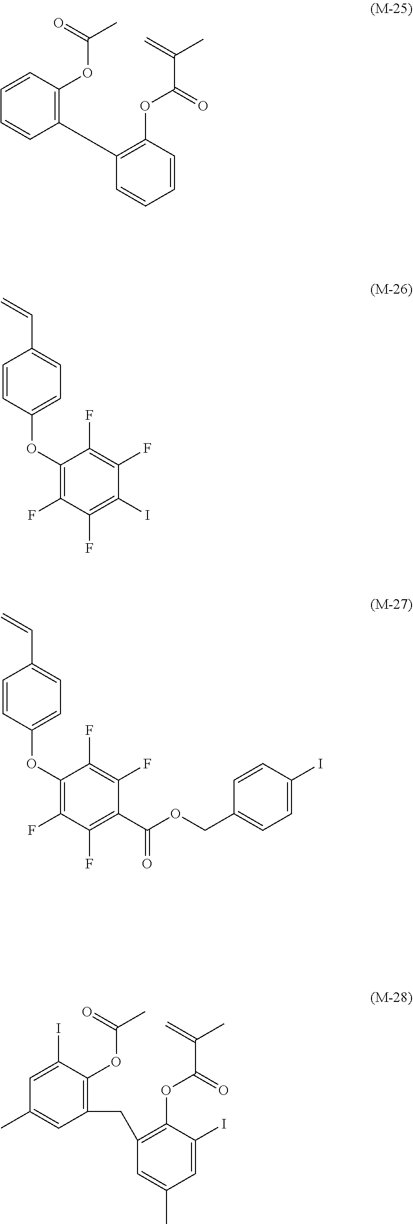

### Synthesis Example 1: Synthesis of Monomer (M-1)

Into a 1-L eggplant-shaped flask were weighed 50.00 g of 2,3,4,5,6-pentafluorobenzoic acid, 5.76 g of 4-dimethylaminopyridine, and 42.2 g of 2-methyl-3-buten-3-ol, which were then dissolved in 200 mL of tetrahydrofuran. A thus resulting solution was cooled to 0° C., and a solution of 55.6 g of N,N′-dicyclohexylcarbodiimide in 100 mL of tetrahydrofuran was added dropwise thereto and then the mixture was stirred at room temperature for 8 hrs. After completion of the reaction, an aqueous saturated ammonium chloride solution was added thereto and extraction with ethyl acetate was conducted, followed by concentration in vacuo. A residue thus obtained was subjected to purification by column chromatography, whereby 59.4 g of a compound represented by the following formula (A) (hereinafter, may be also referred to as “intermediate (A)”) was obtained. A scheme of synthesis of the intermediate (A) is shown below.

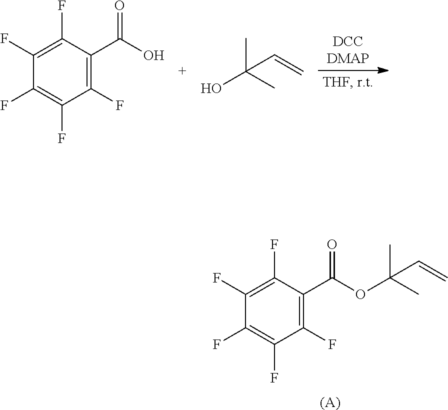

Into a 1-L eggplant-shaped flask were weighed 12.29 g of p-hydroxybenzaldehyde and 28.2 g of the intermediate (A), which were then dissolved in 100 mL of N,N′-dimethylformamide. After a thus resulting solution was cooled to 0° C., 20.87 g of potassium carbonate was added over 30 min, and the mixture was stirred at room temperature for 3 hrs. After completion of the reaction, an aqueous saturated ammonium chloride solution was added thereto and extraction with ethyl acetate was conducted, followed by concentration in vacuo. A residue thus obtained was subjected to purification by column chromatography, whereby 36.3 g of a compound represented by the following formula (B) (hereinafter, may be also referred to as “intermediate (B)”) was obtained. A scheme of synthesis of the intermediate (B) is shown below.

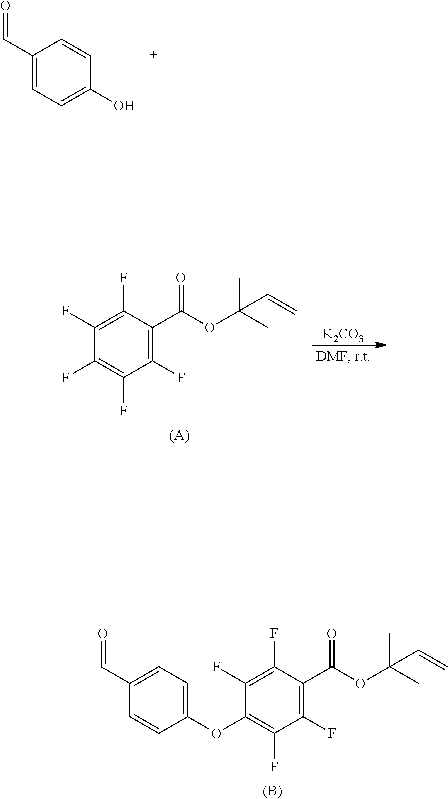

Into a 500-mL eggplant-shaped flask was weighed 22.9 g of zinc, which was then dissolved in 95 mL of N,N′-dimethylformamide. After a thus resulting solution was heated to 50° C., 0.74 g of acetyl chloride was added thereto dropwise and the mixture was stirred for 1 hour. Thereafter, a solution of 36.1 g of the intermediate (B) in dibromomethane (24.6 g) was added dropwise thereto such that the temperature did not exceed 70° C., and the mixture was stirred at 50° C. for 3 hrs. After completion of the reaction, an aqueous saturated ammonium chloride solution was added thereto and extraction with ethyl acetate was conducted, followed by concentration in vacuo. A residue thus obtained was subjected to purification by column chromatography, whereby 23.7 g of a monomer (M-1) was obtained. A scheme of synthesis of the monomer (M-1) is shown below.

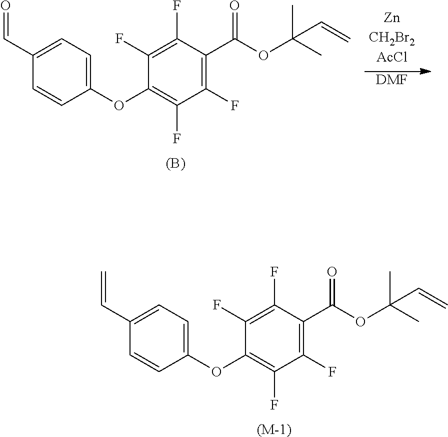

### Synthesis Examples 2 to 22, 26 to 27: Synthesis of Monomers (M-2) to (M-22), (M-26) to (M-27)

Monomers (M-2) to (M-22) and (M-26) to (M-27) were synthesized by an operation similar to that of Synthesis Example 1, except that the precursor was appropriately changed.

### Synthesis Example 23: Synthesis of Monomer (M-23)

Into a 500-mL eggplant-shaped flask were weighed 10.0 g of 1,1′-thiobis(2-naphthol) and 6.35 g of triethylamine, which were then mixed with 200 mL of dichloromethane. To a resultant mixed solution stirred at room temperature, 6.35 g of anhydrous methacrylic acid was added dropwise, and the mixture was further stirred at room temperature for 3 hrs. After completion of the reaction, an aqueous saturated ammonium chloride solution was added thereto and extraction with dichloromethane was conducted, followed by concentration in vacuo. A residue thus obtained was subjected to purification by column chromatography, whereby 11.5 g of a compound represented by the following formula (C) (hereinafter, may be also referred to as “intermediate (C)”) was obtained. A scheme of synthesis of the intermediate (C) is shown below.

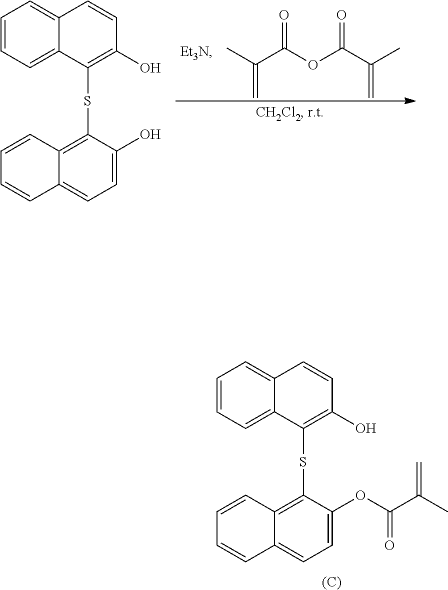

Into a 500-mL eggplant-shaped flask was weighed 11.5 g of the intermediate (C), which was then dissolved in 200 mL of tetrahydrofuran. To a resulting solution stirred at room temperature, 2.83 g of pyridine and 2.81 g of acetyl chloride were each added dropwise, and the mixture was further stirred at room temperature for 6 hrs. After completion of the reaction, an aqueous saturated ammonium chloride solution was added thereto and extraction with ethyl acetate was conducted, followed by concentration in vacuo. A residue thus obtained was subjected to purification by column chromatography, whereby 12.5 g of a monomer (M-23) was obtained. A scheme of synthesis of the monomer (M-23) is shown below.

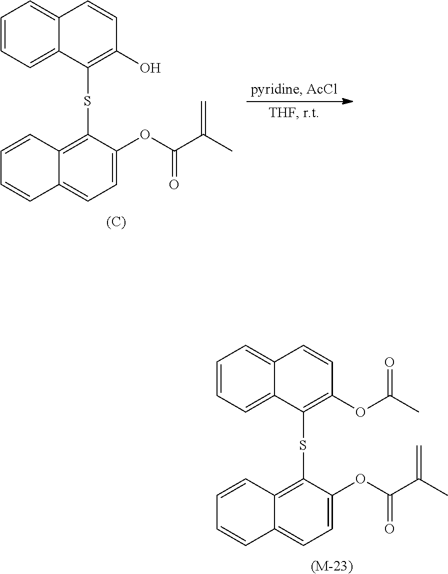

### Synthesis Examples 24 to 25, 28: Synthesis of Monomers (M-24) to (M-25), (M-28)

Monomers (M-24) to (M-25) and (M-28) were synthesized by an operation similar to that of Synthesis Example 23, except that the precursor was appropriately changed.

### Synthesis of Polymer (A) and Polymer (E)

In synthesis of the polymer (A) and the polymer (E), compounds (hereinafter, may be also referred to as “monomers (M-29) to (M-55)”) represented by the following formulae (M-29) to (M-55) were used as monomers other than the monomer (M). It is to be noted that, in the following Synthesis Examples, unless otherwise specified particularly, the term “parts by mass” means a value, provided that the total mass of the monomers used was 100 parts by mass, and the term “mol %” means a value, provided that the total mol number of the monomers used was 100 mol %.

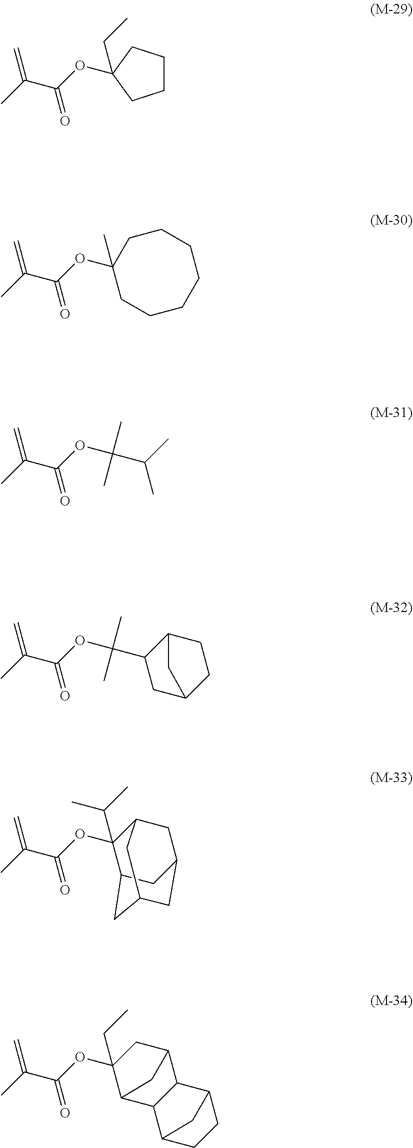

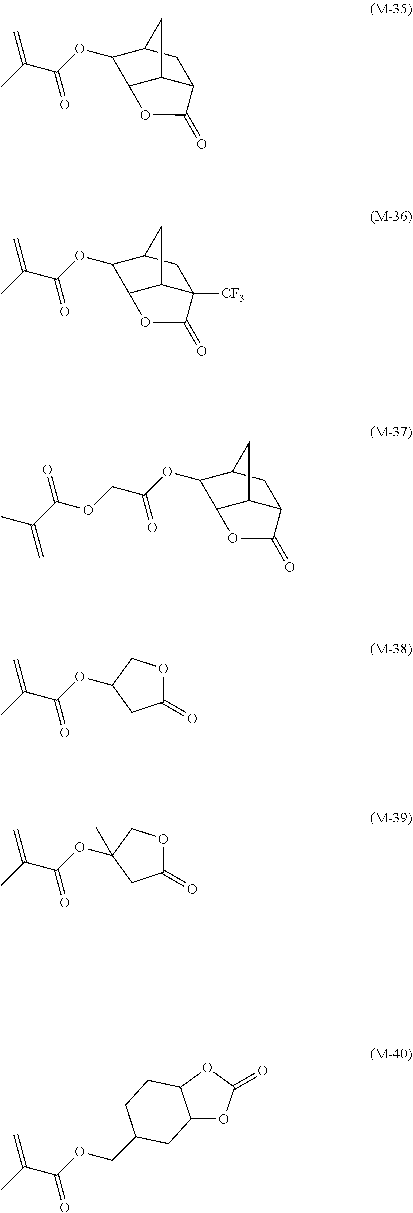 [SMILES: C=C(C)C(=O)OC1C2CC3C(=O)OC1C3C2 ; C=C(C)C(=O)OC1C2CC3C1OC(=O)C3(C(F)(F)F)C2 ; C=C(C)C(=O)OCC(=O)OC1C2CC3C(=O)OC1C3C2 ; C=C(C)C(=O)OC1COC(=O)C1 ; C=C(C)C(=O)OC1(C)COC(=O)C1 ; C=C(C)C(=O)OCC1CCC2OC(=O)OC2C1]

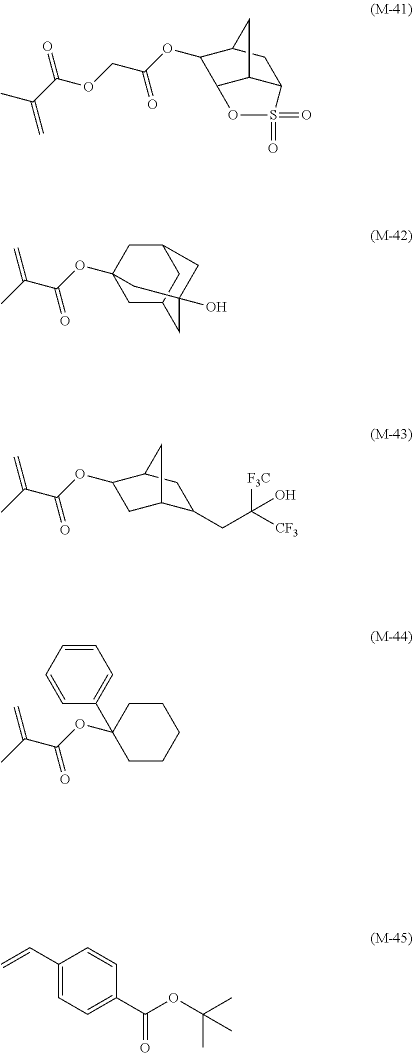 [SMILES: C=C(C)C(=O)OCC(=O)OC1C2CC3C1OS(=O)(=O)C3C2 ; C=C(C)C(=O)OC12CC3CC(CC(O)(C3)C1)C2 ; C=C(C)C(=O)OC1CC2CC1CC2CC(O)(C(F)(F)F)C(F)(F)F ; C=C(C)C(=O)OC1(c2ccccc2)CCCCC1 ; C=Cc1ccc(C(=O)OC(C)(C)C)cc1]

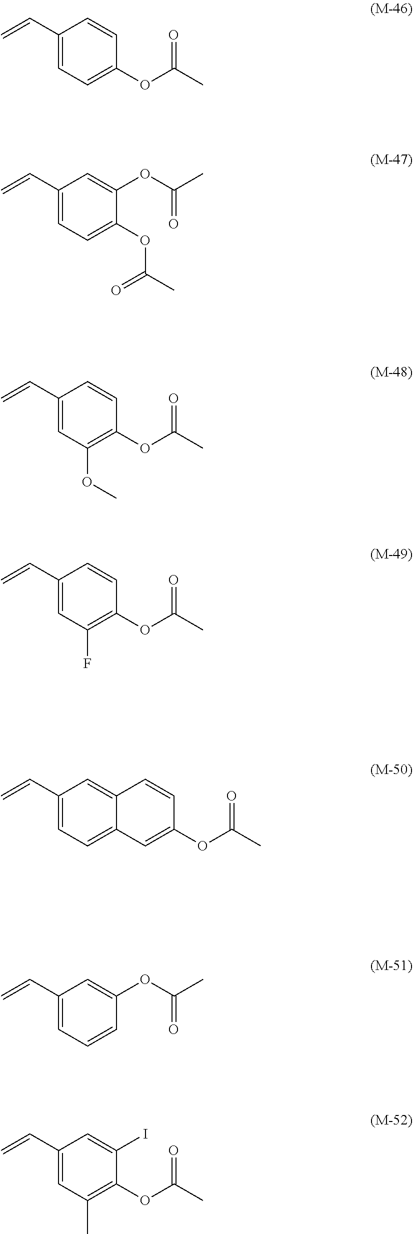

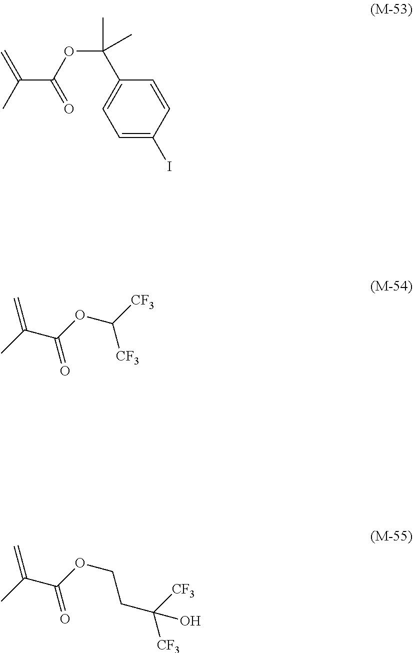 [SMILES: C=C(C)C(=O)OC(C)(C)c1ccc(I)cc1 ; C=C(C)C(=O)OC(C(F)(F)F)C(F)(F)F ; C=C(C)C(=O)OCCC(O)(C(F)(F)F)C(F)(F)F]

### Synthesis Example 29: Synthesis of Polymer (A-1)

The monomer (M-1), the monomer (M-44), and the monomer (M-46) were dissolved in 200 parts by mass of 1-methoxy-2-propanol such that the molar ratio became 20/35/45. Next, 4 mol % azobisisobutyronitrile (hereinafter, may be also referred to as “AIBN”) was added as an initiator to prepare a monomer solution. Meanwhile, 100 parts by mass of 1-methoxy-2-propanol were charged into an empty reaction vessel, and then heated to 85° C. with stirring. Next, the monomer solution prepared as described above was added dropwise to the reaction vessel over 3 hours, then a thus resulting solution was further heated for 3 hours at 85° C. to perform a polymerization reaction for a total of 6 hours. After completion of the polymerization reaction, the polymerization solution was cooled to room temperature.

The polymerization solution thus cooled was charged into hexane (500 parts by mass with respect to the polymerization solution), and a thus precipitated white powder was filtered off. The white powder obtained by the filtration was washed twice with 100 parts by mass of hexane with respect to the polymerization solution, followed by filtering off and dissolution in 1-methoxy-2-propanol (300 parts by mass). Next, methanol (500 parts by mass), triethylamine (50 parts by mass), and ultra-pure water (10 parts by mass) were added to a resulting solution, and a hydrolysis reaction was performed at 70° C. for 6 hours with stirring. After completion of the hydrolysis reaction, the remaining solvent was distilled away and a solid thus obtained was dissolved in acetone (100 parts by mass). The solution was added dropwise to 500 parts by mass of water to permit coagulation of the resin, and a solid thus obtained was filtered off. Drying at 50° C. for 12 hours gave a white powdery polymer (A-1).

The Mw of the polymer (A-1) was 5,500, and the Mw/Mn was 1.44. Furthermore, as a result of the ¹³C-NMR analysis, proportions of the monomers (M-1), (M-44), and (M-46), which were derived from respective structural units, in the polymer (A-1) were 21 mol %, 33 mol %, and 46 mol %, respectively.

### Synthesis Examples 30 to 54, 60 to 66: Synthesis of Polymers (A-2) to (A-26), (A-32) to (A-36), (a-1) and (a-2)

Polymers (A-2) to (A-26), (A-32) to (A-36), (a-1) and (a-2) were synthesized by an operation similar to that of Synthesis Example 29 except that monomers of the type and in the proportion shown in Table 1 below were used. The Mw and the Mw/Mn of each polymer obtained, as well as the proportion of the structural unit derived from each monomer in each polymer are shown together in Table 1 below.

### Synthesis Example 55: Synthesis of Polymer (A-27)

The monomers (M-1), (M-29) and (M-35) were dissolved in 200 parts by mass of 2-butanone such that the molar ratio became 35/20/45. Next, 2 mol % AIBN was added as an initiator to prepare a monomer solution. Meanwhile, 100 parts by mass of 2-butanone were charged into an empty reaction vessel, which was then purged with nitrogen for 30 min. The temperature inside the reaction vessel was elevated to 80° C., and the monomer solution was added dropwise thereto over 3 hrs with stirring. The time of starting the dropwise addition was regarded as the time of starting the polymerization reaction, and the polymerization reaction was allowed to proceed for 6 hrs. After completion of the polymerization reaction, the polymerization solution was cooled to no greater than 30° C. by water cooling. The thus cooled polymerization solution was charged into 2,000 parts by mass of methanol, and a thus precipitated white powder was filtered off. The white powder obtained by the filtration was washed twice with 400 parts by mass of methanol and filtered off, followed by drying at 60° C. for 15 hrs to give a white powdery polymer (A-27) with a favorable yield.

The Mw of the polymer (A-27) was 6,000, and the Mw/Mn was 1.44. Furthermore, as a result of the ¹³C-NMR analysis, proportions of the monomers (M-1), (M-29), and (M-35), which were derived from respective structural units, in the polymer (A-27) were 38 mol %, 16 mol %, and 46 mol %, respectively.

### Synthesis Examples 56 to 59: Synthesis of Polymers (A-28) to (A-31)

Polymers (A-28) to (A-31) were synthesized by an operation similar to that of Synthesis Example 55 except that monomers of the type and in the proportion shown in Table 1 below were used. The Mw and the Mw/Mn of each polymer obtained, as well as the proportion of the structural unit derived from each monomer in each polymer are shown together in Table 1 below.

In Table 1 below, “-” indicates that the corresponding component was not used.

TABLE 1

| | | Monomer that gives | | | Monomer that gives | | | Monomer that gives | | | Monomer that gives | | | | |
|---|---|---|---|---|---|---|---|---|---|---|---|---|---|---|---|
| | | structural unit (I) | | | structural unit (II) | | | structural unit (III) | | | structural unit (IV) | | | | |
| | | | | propor- | | | propor- | | | propor- | | | propor- | | |
| | | | | tion of | | | tion of | | | tion of | | | tion of | | |
| | | | | struc- | | | struc- | | | struc- | | | struc- | Physical | |
| | (A) | | amount | tural | | amount | tural | | amount | tural | | amount | tural | property values | |
| | Poly- | | used | unit | | used | unit | | used | unit | | used | unit | | Mw/ |
| | mer | type | (mol %) | (mol %) | type | (mol %) | (mol %) | type | (mol %) | (mol %) | type | (mol %) | (mol %) | Mw | Mn |
| Synthesis | A-1 | M-1 | 20 | 21 | M-44 | 35 | 33 | M-46 | 45 | 46 | — | — | — | 5500 | 1.44 |
| Example 29 | | | | | | | | | | | | | | | |
| Synthesis | A-2 | M-2 | 15 | 16 | M-29 | 45 | 17 | M-46 | 40 | 67 | — | — | — | 5200 | 1.50 |
| Example 30 | | | | | | | | | | | | | | | |
| Synthesis | A-3 | M-3 | 15 | 16 | M-32 | 40 | 40 | M-46 | 45 | 44 | — | — | — | 6500 | 1.43 |
| Example 31 | | | | | | | | | | | | | | | |
| Synthesis | A-4 | M-4 | 25 | 27 | M-33 | 35 | 32 | M-47 | 40 | 41 | — | — | — | 5800 | 1.39 |
| Example 32 | | | | | | | | | | | | | | | |
| Synthesis | A-5 | M-5 | 30 | 32 | M-34 | 15 | 12 | M-46 | 55 | 56 | — | — | — | 7000 | 1.44 |
| Example 33 | | | | | | | | | | | | | | | |
| Synthesis | A-6 | M-6 | 15 | 16 | M-31 | 20 | 17 | M-45/ | 25/40 | 26/41 | — | — | — | 4500 | 1.52 |
| Example 34 | | | | | | | | M-46 | | | | | | | |
| Synthesis | A-7 | M-7 | 5 | 5 | M-30 | 35 | 32 | M-49/ | 40/20 | 41/22 | — | — | — | 7500 | 1.40 |
| Example 35 | | | | | | | | M-50 | | | | | | | |
| Synthesis | A-8 | M-8 | 20 | 21 | M-29 | 35 | 34 | M-46 | 45 | 45 | — | — | — | 7400 | 1.47 |
| Example 36 | | | | | | | | | | | | | | | |
| Synthesis | A-9 | M-9 | 20 | 18 | M-31 | 40 | 37 | M-50 | 40 | 45 | — | — | — | 4900 | 1.37 |
| Example 37 | | | | | | | | | | | | | | | |
| Synthesis | A-10 | M-10 | 20 | 21 | M-30 | 35 | 33 | M-46 | 45 | 46 | — | — | — | 6900 | 1.38 |
| Example 38 | | | | | | | | | | | | | | | |
| Synthesis | A-11 | M-11 | 30 | 32 | M-44 | 35 | 32 | M-46 | 35 | 36 | — | — | — | 5500 | 1.55 |
| Example 39 | | | | | | | | | | | | | | | |
| Synthesis | A-12 | M-12 | 25 | 26 | M-44 | 40 | 37 | M-46/ | 25/10 | 26/11 | — | — | — | 7000 | 1.51 |
| Example 40 | | | | | | | | M-50 | | | | | | | |
| Synthesis | A-13 | M-13 | 20 | 21 | M-29 | 35 | 33 | M-46/ | 35/10 | 35/11 | — | — | — | 4500 | 1.47 |
| Example 41 | | | | | | | | M-48 | | | | | | | |
| Synthesis | A-14 | M-14 | 20 | 21 | M-44 | 25 | 22 | M-51 | 55 | 57 | — | — | — | 5500 | 1.48 |
| Example 42 | | | | | | | | | | | | | | | |
| Synthesis | A-15 | M-15 | 25 | 26 | M-29 | 35 | 32 | M-46 | 40 | 42 | — | — | — | 5200 | 1.42 |
| Example 43 | | | | | | | | | | | | | | | |
| Synthesis | A-16 | M-16 | 20 | 21 | M-44 | 35 | 33 | M-46 | 45 | 46 | — | — | — | 7800 | 1.41 |
| Example 44 | | | | | | | | | | | | | | | |
| Synthesis | A-17 | M-17 | 10 | 12 | M-29/ | 20/35 | 19/33 | M-46 | 35 | 36 | — | — | — | 5700 | 1.40 |
| Example 45 | | | | | M-44 | | | | | | | | | | |
| Synthesis | A-18 | M-18 | 5 | 6 | M-30/ | 35/30 | 33/29 | M-47 | 30 | 32 | — | — | — | 6500 | 1.39 |
| Example 46 | | | | | M-31 | | | | | | | | | | |
| Synthesis | A-19 | M-19 | 20 | 22 | M-29/ | 25/20 | 23/18 | M-51 | 35 | 37 | — | — | — | 4800 | 1.37 |
| Example 47 | | | | | M-44 | | | | | | | | | | |
| Synthesis | A-20 | M-20 | 20 | 21 | M-29 | 45 | 43 | M-46 | 35 | 36 | — | — | — | 5000 | 1.51 |
| Example 48 | | | | | | | | | | | | | | | |
| Synthesis | A-21 | M-21 | 10 | 12 | M-31/ | 20/35 | 19/33 | M-46 | 35 | 36 | — | — | — | 6400 | 1.53 |
| Example 49 | | | | | M-34 | | | | | | | | | | |
| Synthesis | A-22 | M-22 | 25 | 25 | M-44 | 40 | 38 | M-46 | 35 | 37 | — | — | — | 8000 | 1.52 |
| Example 50 | | | | | | | | | | | | | | | |
| Synthesis | A-23 | M-23 | 10 | 10 | M-29 | 55 | 52 | M-46 | 35 | 38 | — | — | — | 5200 | 1.47 |
| Example 51 | | | | | | | | | | | | | | | |
| Synthesis | A-24 | M-24 | 20 | 19 | M-32 | 40 | 35 | M-46 | 40 | 46 | — | — | — | 7600 | 1.52 |
| Example 52 | | | | | | | | | | | | | | | |
| Synthesis | A-25 | M-25 | 15 | 16 | M-31 | 60 | 57 | M-51 | 15 | 27 | — | — | — | 6300 | 1.50 |
| Example 53 | | | | | | | | | | | | | | | |
| Synthesis | A-26 | M-1 | 20 | 21 | M-44 | 25 | 25 | M-46 | 35 | 36 | M-43 | 20 | 18 | 5500 | 1.49 |
| Example 54 | | | | | | | | | | | | | | | |
| Synthesis | A-27 | M-1 | 35 | 38 | M-29 | 20 | 16 | — | — | — | M-35 | 45 | 46 | 6000 | 1.44 |
| Example 55 | | | | | | | | | | | | | | | |
| Synthesis | A-28 | M-2 | 25 | 26 | M-30 | 35 | 33 | — | — | — | M-36 | 40 | 41 | 6500 | 1.42 |
| Example 56 | | | | | | | | | | | | | | | |
| Synthesis | A-29 | M-5 | 15 | 16 | M-29 | 50 | 47 | — | — | — | M-37/ | 20/15 | 22/15 | 6000 | 1.50 |
| Example 57 | | | | | | | | | | | M-39 | | | | |
| Synthesis | A-30 | M-1 | 10 | 11 | M-44 | 35 | 33 | — | — | — | M-38/ | 30/25 | 30/26 | 5200 | 1.47 |
| Example 58 | | | | | | | | | | | M-40 | | | | |
| Synthesis | A-31 | M-2 | 35 | 36 | M-31 | 30 | 28 | — | — | — | M-41/ | 15/20 | 16/20 | 6100 | 1.37 |
| Example 59 | | | | | | | | | | | M-42 | | | | |
| Synthesis | A-32 | M-26 | 10 | 10 | M-29 | 35 | 34 | M-46 | 55 | 56 | — | — | — | 6600 | 1.40 |
| Example 60 | | | | | | | | | | | | | | | |
| Synthesis | A-33 | M-27 | 5 | 5 | M-29 | 35 | 33 | M-46 | 60 | 62 | — | — | — | 6200 | 1.41 |
| Example 61 | | | | | | | | | | | | | | | |
| Synthesis | A-34 | M-28 | 5 | 4 | M-29 | 35 | 35 | M-46 | 60 | 61 | — | — | — | 5500 | 1.43 |
| Example 62 | | | | | | | | | | | | | | | |
| Synthesis | A-35 | M-1 | 10 | 10 | M-29/ | 10/20 | 9/20 | M-46 | 60 | 61 | — | — | — | 5700 | 1.44 |
| Example 63 | | | | | M-53 | | | | | | | | | | |
| Synthesis | A-36 | M-2 | 20 | 20 | M-29 | 35 | 34 | M-46/ | 30/15 | 31/15 | — | — | — | 5800 | 1.50 |
| Example 64 | | | | | | | | M-52 | | | | | | | |
| Synthesis | a-1 | — | — | — | M-44/ | 35/20 | 33/21 | M-46 | 45 | 46 | — | — | — | 5500 | 1.44 |
| Example 65 | | | | | M-45 | | | | | | | | | | |
| Synthesis | a-2 | — | — | — | M-29/ | 25/20 | 23/18 | M-46/ | 20/35 | 22/37 | — | — | — | 4900 | 1.50 |
| Example 66 | | | | | M-44 | | | M-51 | | | | | | | |

### Synthesis Example 67: Synthesis of Polymer (E-1)

The monomers (M-30) and (M-54) were dissolved in 200 parts by mass of 2-butanone such that the molar ratio became 45/55. Next, 5 mol % AIBN was added as an initiator to prepare a monomer solution. Meanwhile, 100 parts by mass of 2-butanone were charged into an empty reaction vessel, which was then purged with nitrogen for 30 min. The temperature inside the reaction vessel was elevated to 80° C., and the monomer solution was added dropwise thereto over 3 hrs with stirring. The time of starting the dropwise addition was regarded as the time of starting the polymerization reaction, and the polymerization reaction was allowed to proceed for 6 hrs. After completion of the polymerization reaction, the polymerization solution was cooled to no greater than 30° C. by water cooling. The solvent was replaced with 400 parts by mass of acetonitrile, and then an operation of adding 100 parts by mass of hexane and stirring to collect an acetonitrile layer was repeated three times. The solvent was replaced with propylene glycol monomethyl ether acetate to give a solution of the polymer (E-1) with a favorable yield.

The Mw of the polymer (E-1) was 5,600, and the Mw/Mn was 1.69. Furthermore, as a result of the ¹³C-NMR analysis, proportions of the monomers (M-30) and (M-54), which were derived from respective structural units, in the polymer (E-1) were 44 mol % and 56 mol %, respectively.

### Synthesis Example 68: Synthesis of Polymer (E-2)

A polymer (E-2) was synthesized by an operation similar to that of Synthesis Example 67 except that monomers of the type and in the proportion shown in Table 2 below were used. The Mw and the Mw/Mn of the polymer (E-2) obtained, as well as the proportion of the structural unit derived from each monomer in the polymer (E-2) are shown together in Table 2 below.

TABLE 2

| | | Monomer that gives | | | Monomer that gives other | | | | |
|---|---|---|---|---|---|---|---|---|---|
| | | structural unit (I′) | | | structural unit | | | | |
| | | | | proportion | | | proportion | | |
| | | | amount | of structural | | amount | of structural | Physical | |
| | (E) | | used | unit | | used | unit | property values | |
| | Polymer | type | (mol %) | (mol %) | type | (mol %) | (mol %) | Mw | Mw/Mn |
| Synthesis | E-1 | M-54 | 55 | 56 | M-30 | 45 | 44 | 5600 | 1.69 |
| Example 67 | | | | | | | | | |
| Synthesis | E-2 | M-55 | 60 | 59 | M-29 | 40 | 41 | 6700 | 1.78 |
| Example 68 | | | | | | | | | |

### Preparation of Radiation-Sensitive Resin Composition

The acid generating agent (B), the acid diffusion control agent (C), and the organic solvent (D) used in preparing each radiation-sensitive resin composition are shown below. It is to be noted that unless otherwise specified particularly, the term “parts by mass” means a value, provided that the mass of the polymer (A) used was 100 parts by mass.

(B) Acid Generating Agent

Compounds (hereinafter, may be also referred to as “acid generating agents (B-1) to (B-13)”) represented by the following formulae (B-1) to (B-13) were used as the acid generating agent (B).

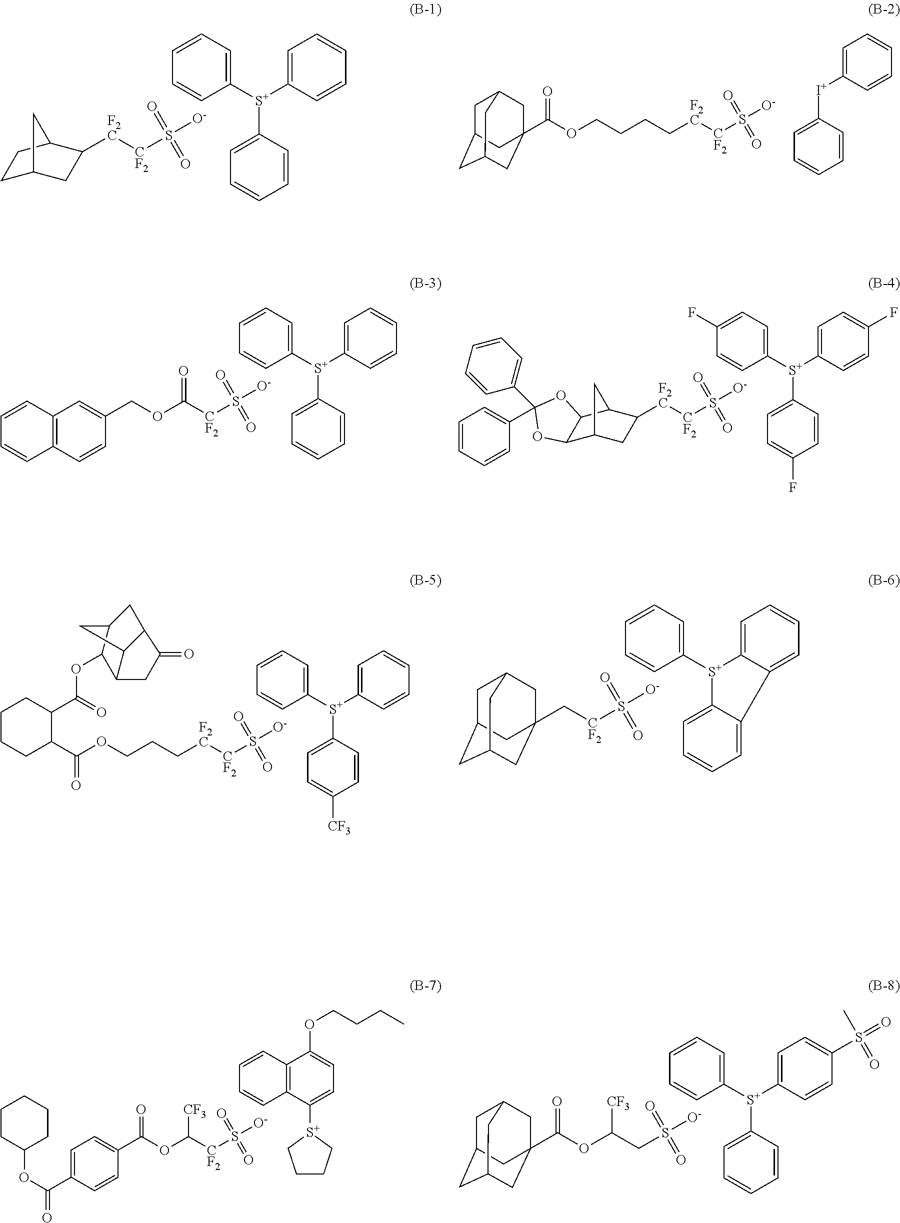

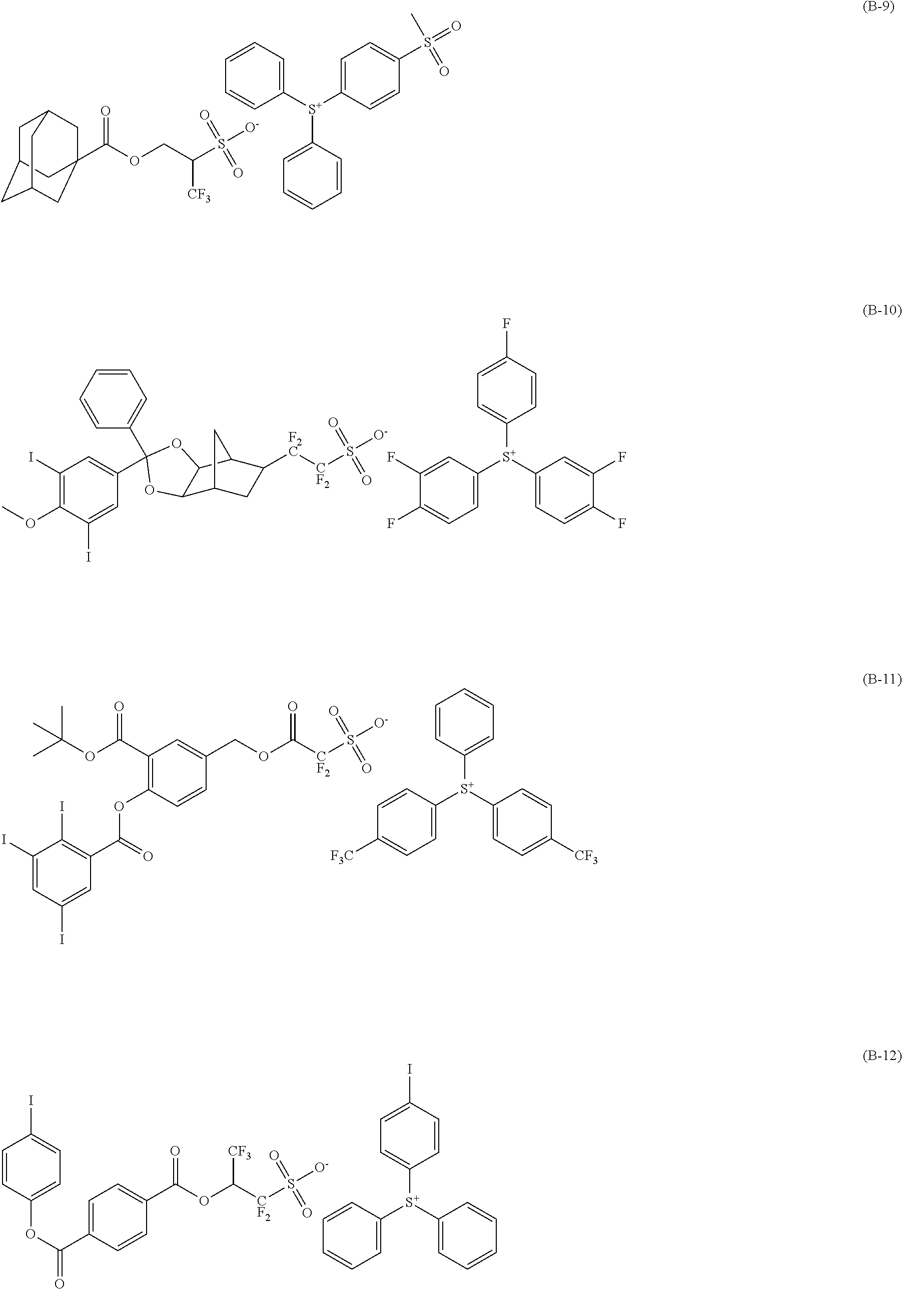

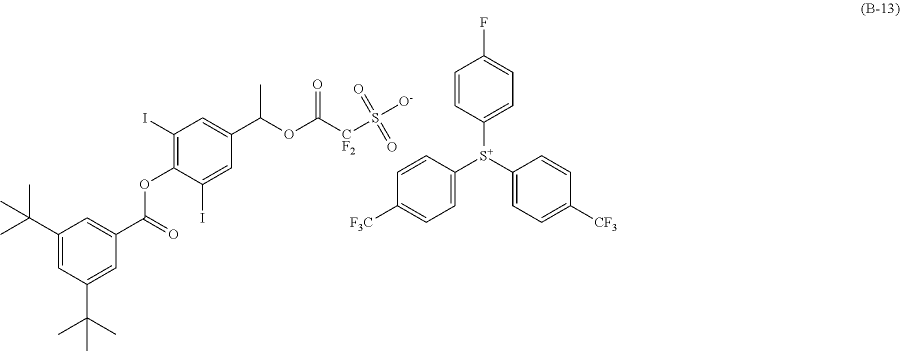 [SMILES: CC(OC(=O)C(F)(F)S(=O)(=O)[O-])c1cc(I)c(OC(=O)c2cc(C(C)(C)C)cc(C(C)(C)C)c2)c(I)c1 ; Fc1ccc([S+](c2ccc(C(F)(F)F)cc2)c2ccc(C(F)(F)F)cc2)cc1]

(C) Acid Diffusion Control Agent

Compounds (hereinafter, may be also referred to as “acid diffusion control agents (C-1) to (C-8)”) represented by the following formulae (C-1) to (C-8) were used as the acid diffusion control agent (C).

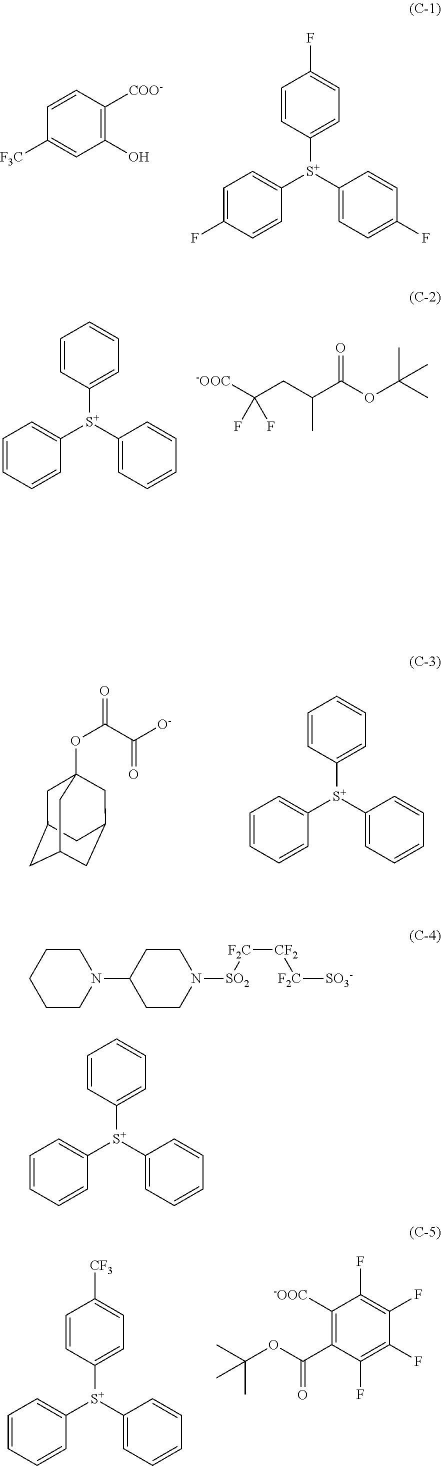

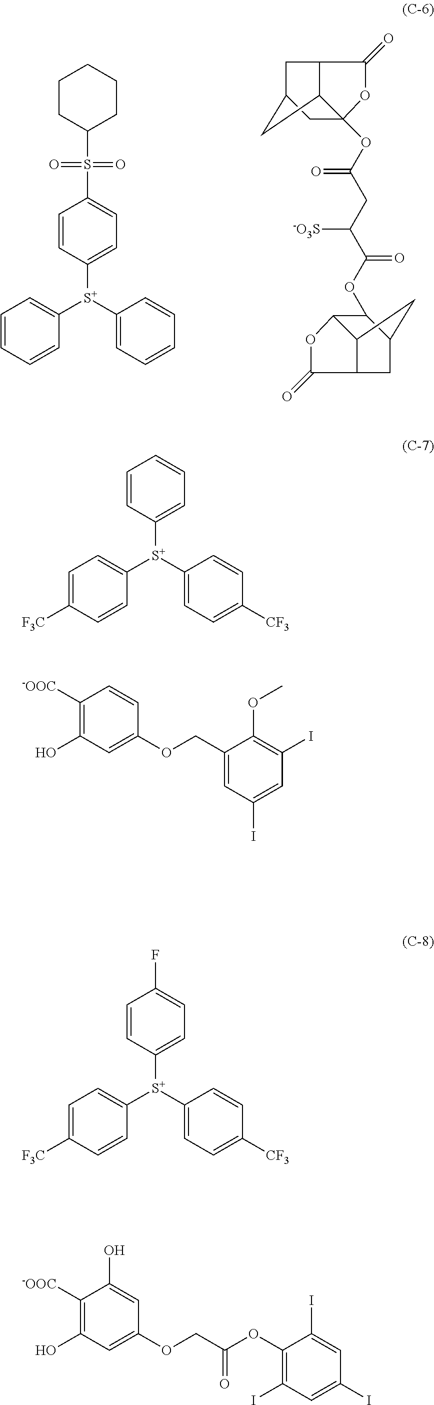

(D) Organic Solvent

(D-1) to (D-4) below were used as the organic solvent (D).

(D-1): propylene acetate glycol 1-monomethyl ether

(D-2): ethyl lactate

(D-3): γ-butyrolactone

(D-4): propylene glycol 1-monomethyl ether

### Example 1: Preparation of Radiation-Sensitive Resin Composition (J-1)

A radiation-sensitive resin composition (J-1) was prepared by: mixing 100 parts by mass of (A-1) as the polymer (A), 45 parts by mass of (B-4) as the acid generating agent (B), 15 parts by mass of (C-1) as the acid diffusion control agent (C), 4,280 parts by mass of (D-1) and 1,830 parts by mass of (D-4) as the organic solvent (D), and 3 parts by mass of (E-1) as the polymer (E); and filtering a resulting mixture through a membrane filter having a pore size of 0.2 μm.

### Examples 2 to 36 and Comparative Examples 1 to 2: Preparation of Radiation-Sensitive Resin Compositions (J-2) to (J-36) and (CJ-1) to (CJ-2)

Radiation-sensitive resin compositions (J-2) to (J-36) and (CJ-1) to (CJ-2) were prepared in a similar manner to Example 1, except that for each component, the type and content shown in Table 3 below were used.

TABLE 3

| | | | | (B) Acid generating | | (C) Acid diffusion | | | | | |
|---|---|---|---|---|---|---|---|---|---|---|---|
| | Radiation- | (A) Polymer | | agent | | control agent | | (E) Polymer | | (D) Organic solvent | |
| | sensitive | | content | | content | | content | | content | | content |
| | resin | | (parts by | | (parts by | | (parts by | | (parts by | | (parts by |
| | composition | type | mass) | type | mass) | type | mass) | type | mass) | type | mass) |
| Example 1 | J-1 | A-1 | 100 | B-4 | 45 | C-1 | 15 | E-2 | 3 | D-1/D-4 | 4,280/1,830 |
| Example 2 | J-2 | A-2 | 100 | B-5 | 50 | C-2 | 20 | E-2 | 3 | D-1/D-4 | 4,280/1,830 |
| Example 3 | J-3 | A-3 | 100 | B-7 | 40 | C-3 | 15 | E-2 | 3 | D-1/D-4 | 4,280/1,830 |
| Example 4 | J-4 | A-4 | 100 | B-4 | 45 | C-1 | 15 | E-2 | 3 | D-1/D-4 | 4,280/1,830 |
| Example 5 | J-5 | A-5 | 100 | B-3 | 55 | C-2 | 20 | E-2 | 3 | D-1/D-3/D-4 | 4,280/1,800/30 |
| Example 6 | J-6 | A-6 | 100 | B-4 | 40 | C-5 | 15 | E-2 | 3 | D-1/D-4 | 4,280/1,830 |
| Example 7 | J-7 | A-7 | 100 | B-2 | 35 | C-4 | 20 | E-2 | 3 | D-1/D-4 | 4,280/1,830 |
| Example 8 | J-8 | A-8 | 100 | B-1 | 30 | C-2 | 20 | E-2 | 3 | D-1/D-4 | 4,280/1,830 |
| Example 9 | J-9 | A-9 | 100 | B-3 | 45 | C-2 | 20 | E-2 | 3 | D-1/D-3/D-4 | 4,280/1,800/30 |
| Example 10 | J-10 | A-10 | 100 | B-9 | 55 | C-2 | 15 | E-2 | 3 | D-1/D-4 | 4,280/1,830 |
| Example 11 | J-11 | A-11 | 100 | B-4 | 45 | C-1 | 15 | E-2 | 3 | D-1/D-4 | 4,280/1,830 |
| Example 12 | J-12 | A-12 | 100 | B-6 | 35 | C-3 | 20 | E-2 | 3 | D-1/D-2 | 4,890/1,220 |
| Example 13 | J-13 | A-13 | 100 | B-4 | 40 | C-1 | 15 | E-2 | 3 | D-1/D-4 | 4,280/1,830 |
| Example 14 | J-14 | A-14 | 100 | B-5 | 45 | C-2 | 20 | E-2 | 3 | D-1/D-4 | 4,280/1,830 |
| Example 15 | J-15 | A-15 | 100 | B-4 | 50 | C-1 | 20 | E-2 | 3 | D-1/D-4 | 4,280/1,830 |
| Example 16 | J-16 | A-16 | 100 | B-4 | 45 | C-1 | 15 | E-2 | 3 | D-1/D-4 | 4,280/1,830 |
| Example 17 | J-17 | A-17 | 100 | B-8 | 35 | C-2 | 15 | E-2 | 3 | D-1/D-4 | 4,280/1,830 |
| Example 18 | J-18 | A-18 | 100 | B-5 | 55 | C-3 | 15 | E-2 | 3 | D-1/D-4 | 4,280/1,830 |
| Example 19 | J-19 | A-19 | 100 | B-4 | 50 | C-1 | 25 | E-2 | 3 | D-1/D-4 | 4,280/1,830 |
| Example 20 | J-20 | A-20 | 100 | B-5 | 40 | C-2 | 20 | E-2 | 3 | D-1/D-4 | 4,280/1,830 |
| Example 21 | J-21 | A-21 | 100 | B-7 | 45 | C-3 | 15 | E-2 | 3 | D-1/D-4 | 4,280/1,830 |
| Example 22 | J-22 | A-22 | 100 | B-3 | 40 | C-2 | 15 | E-2 | 3 | D-1/D-3/D-4 | 4,280/1,800/30 |
| Example 23 | J-23 | A-23 | 100 | B-2 | 30 | C-1 | 15 | E-2 | 3 | D-1/D-4 | 4,280/1,830 |
| Example 24 | J-24 | A-24 | 100 | B-5 | 40 | C-3 | 45 | E-2 | 3 | D-1/D-4 | 4,280/1,830 |
| Example 25 | J-25 | A-25 | 100 | B-1 | 35 | C-2 | 30 | E-2 | 3 | D-1/D-4 | 4,280/1,830 |
| Example 26 | J-26 | A-26 | 100 | B-6 | 45 | C-6 | 30 | E-1 | 5 | D-1/D-2 | 4,890/1,220 |
| Example 27 | J-27 | A-27 | 100 | B-9 | 50 | C-6 | 25 | E-1 | 5 | D-1/D-4 | 4,280/1,830 |
| Example 28 | J-28 | A-28 | 100 | B-6 | 40 | C-2 | 15 | E-1 | 5 | D-1/D-2 | 4,890/1,220 |
| Example 29 | J-29 | A-29 | 100 | B-6 | 45 | C-2 | 20 | E-1 | 5 | D-1/D-2 | 4,890/1,220 |
| Example 30 | J-30 | A-30 | 100 | B-6 | 55 | C-6 | 30 | E-1 | 5 | D-1/D-2 | 4,890/1,220 |
| Example 31 | J-31 | A-31 | 100 | B-8 | 35 | C-2 | 15 | E-1 | 5 | D-1/D-4 | 4,280/1,830 |
| Example 32 | J-32 | A-32 | 100 | B-4 | 45 | C-1 | 15 | E-1 | 5 | D-1/D-4 | 4,280/1,830 |
| Example 33 | J-33 | A-33 | 100 | B-10 | 50 | C-1 | 15 | E-1 | 5 | D-1/D-4 | 4,280/1,830 |
| Example 34 | J-34 | A-34 | 100 | B-13 | 65 | C-7 | 15 | E-1 | 5 | D-1/D-4 | 4,280/1,830 |
| Example 35 | J-35 | A-35 | 100 | B-11 | 60 | C-8 | 15 | E-1 | 5 | D-1/D-4 | 4,280/1,830 |
| Example 36 | J-36 | A-36 | 100 | B-12 | 55 | C-1 | 15 | E-1 | 5 | D-1/D-4 | 4,280/1,830 |
| Comparative | CJ-1 | a-1 | 100 | B-4 | 45 | C-1 | 15 | E-2 | 3 | D-1/D-4 | 4,280/1,830 |
| Example 1 | | | | | | | | | | | |
| Comparative | CJ-2 | a-2 | 100 | B-4 | 50 | C-1 | 25 | E-2 | 3 | D-1/D-4 | 4,280/1,830 |
| Example 2 | | | | | | | | | | | |

### Formation of Resist Pattern

An underlayer antireflective film having an average thickness of 105 nm was formed by applying a composition for underlayer antireflective film formation (“ARC66,” available from Brewer Science, Inc.) on a 12-inch silicon wafer using a spin-coater (“CLEAN TRACK ACT 12,” available from Tokyo Electron Limited), and thereafter heating the composition at 205° C. for 60 sec. Each radiation-sensitive resin composition prepared as described above was applied on the underlayer antireflective film using the spin-coater, and subjected to PB at 130° C. for 60 sec. Thereafter, by cooling at 23° C. for 30 sec, a resist film having an average thickness of 55 nm was formed. Next, the resist pattern was exposed using an EUV scanner (model “NXE3300,” available from ASML Co.) with NA of 0.33 under an illumination condition of Conventional s=0.89, and with a mask of imecDEFECT32FFR02. After the exposure, PEB was carried out at 120° C. for 60 sec. Thereafter, the resist film was subjected to development with an alkali using a 2.38% by mass aqueous TMAH solution as an alkaline developer solution. After the development, washing with water was carried out, followed by further drying, to form a positive-tone resist pattern (32 nm line-and-space pattern).

### Evaluations

The resist patterns formed using the radiation-sensitive resin compositions were evaluated on the sensitivity, the LWR performance, and the CDU performance in accordance with the following methods. The results are shown in Table 4 below. It is to be noted that line width measurement of the resist patterns was performed using a scanning electron microscope (“CG-5000,” available from Hitachi High-Technologies Corporation).

Sensitivity

An exposure dose at which a 32 nm line-and-space pattern was formed in the aforementioned resist pattern formation using the radiation-sensitive resin composition was defined as an optimum exposure dose, and this optimum exposure dose was adopted as Eop (units: mJ/cm²). The sensitivity was evaluated to be: “favorable” in a case of Eop being no greater than 35.0 mJ/cm²; and “unfavorable” in a case of Eop being greater than 35.0 mJ/cm².

LWR Performance

A mask size was adjusted such that a 32 nm line-and-space pattern was formed by irradiating at the exposure dose of Eop determined as in the evaluation of “Sensitivity” above, and a resist pattern was formed. The resist pattern thus formed was observed from above using the scanning electron microscope. Variance of line widths was measured at 50 sites in total, and then a 3 Sigma value was determined from distribution of the measurement values and the 3 Sigma value was defined as LWR (units: nm). The LWR value being smaller indicates more favorable LWR performance, revealing less unevenness of the lines. The LWR performance was evaluated to be: “favorable” in a case of LWR being no greater than 2.50 nm; and “unfavorable” in a case of LWR being greater than 2.50 nm.

CDU Performance

A mask size was adjusted such that a pattern with 35 nm hole diameter and 90 nm pitch was formed by irradiating at the exposure dose of Eop determined as in the evaluation of “Sensitivity” above, and a resist pattern was formed. The resist pattern thus formed was observed from above using the scanning electron microscope. An averaged value of hole diameters at 16 sites measured in a region of 500 nm×500 nm was defined as the average value of the hole diameters in the aforementioned area. The average value of the hole diameters was measured at 500 sites in total within arbitrary 500 nm×500 nm regions, and then a 1 Sigma value was determined from distribution of the measurement values and defined as “CDU” (units: nm). The CDU value being smaller indicates more favorable CDU performance, revealing less variance of the hole diameters in greater ranges. The CDU performance was evaluated to be: “favorable” in a case of CDU being no greater than 2.00 nm; and “unfavorable” in a case of CDU being greater than 2.00 nm.

TABLE 4

| | Radiation- | | | |
|---|---|---|---|---|
| | sensitive resin | Eop | LWR | CDU |
| | composition | (mJ/cm²) | (nm) | (nm) |
| Example 1 | J-1 | 34.0 | 2.14 | 1.71 |
| Example 2 | J-2 | 34.1 | 2.12 | 1.69 |
| Example 3 | J-3 | 33.5 | 2.24 | 1.80 |
| Example 4 | J-4 | 34.2 | 2.14 | 1.72 |
| Example 5 | J-5 | 33.1 | 2.28 | 1.83 |
| Example 6 | J-6 | 33.9 | 2.27 | 1.81 |
| Example 7 | J-7 | 34.8 | 2.44 | 1.95 |
| Example 8 | J-8 | 34.0 | 2.34 | 1.88 |
| Example 9 | J-9 | 34.2 | 2.18 | 1.75 |
| Example 10 | J-10 | 33.9 | 2.21 | 1.76 |
| Example 11 | J-11 | 34.5 | 2.32 | 1.85 |
| Example 12 | J-12 | 33.5 | 2.27 | 1.82 |
| Example 13 | J-13 | 33.1 | 2.14 | 1.71 |
| Example 14 | J-14 | 32.8 | 2.21 | 1.77 |
| Example 15 | J-15 | 34.1 | 2.14 | 1.70 |
| Example 16 | J-16 | 34.5 | 2.45 | 1.96 |
| Example 17 | J-17 | 33.8 | 2.44 | 1.94 |
| Example 18 | J-18 | 34.0 | 2.36 | 1.89 |
| Example 19 | J-19 | 34.0 | 2.27 | 1.81 |
| Example 20 | J-20 | 33.5 | 2.35 | 1.87 |
| Example 21 | J-21 | 33.5 | 2.34 | 1.88 |
| Example 22 | J-22 | 34.0 | 2.45 | 1.97 |
| Example 23 | J-23 | 32.0 | 2.30 | 1.91 |
| Example 24 | J-24 | 33.5 | 2.41 | 1.89 |
| Example 25 | J-25 | 34.0 | 2.28 | 1.87 |
| Example 26 | J-26 | 33.5 | 2.24 | 1.80 |
| Example 27 | J-27 | 34.0 | 2.29 | 1.82 |
| Example 28 | J-28 | 34.0 | 2.31 | 1.84 |
| Example 29 | J-29 | 33.2 | 2.28 | 1.82 |
| Example 30 | J-30 | 33.8 | 2.35 | 1.87 |
| Example 31 | J-31 | 34.5 | 2.34 | 1.88 |
| Example 32 | J-32 | 33.5 | 2.19 | 1.77 |
| Example 33 | J-33 | 33.8 | 2.21 | 1.71 |
| Example 34 | J-34 | 34.0 | 2.25 | 1.78 |
| Example 35 | J-35 | 34.0 | 2.19 | 1.72 |
| Example 36 | J-36 | 33.5 | 2.20 | 1.73 |
| Comparative | CJ-1 | 35.5 | 2.93 | 2.34 |
| Example 1 | | | | |
| Comparative | CJ-2 | 35.0 | 2.86 | 2.29 |
| Example 2 | | | | |

As is clear from the results shown in Table 4, all the radiation-sensitive resin compositions of Examples were favorable in terms of the sensitivity, the LWR performance, and the CDU performance, as compared with the radiation-sensitive resin compositions of Comparative Examples.

According to the radiation-sensitive resin composition and the method of forming a resist pattern of the embodiments of the present invention, forming a resist pattern is enabled with favorable sensitivity to exposure light and superiority in terms of the LWR performance and the CDU performance. Therefore, the radiation-sensitive resin composition and the method of forming a resist pattern of the embodiments of the present invention can be suitably used for working processes of semiconductor devices, and the like, in which microfabrication is expected to be further in progress hereafter.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a polymer, solubility of which in a developer solution is capable of being altered by an action of an acid, and which comprises a structural unit represented by formula (1); and
a radiation-sensitive acid generating agent, 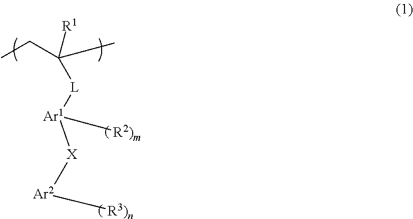
wherein, in the formula (1), R¹ represents a hydrogen atom, a methyl group, or a trifluoromethyl group; L represents a single bond, —COO—, —O—, or —CONH—; Ar¹ represents a group obtained by removing (m+2) hydrogen atoms from an aromatic ring having 6 to 30 ring atoms; X represents a single bond, —O—, -G-O—, —CH₂—, —S—, —SO₂—, —NR^{A}—, or —CONH—, wherein G represents a divalent aliphatic hydrocarbon group having 1 to 20 carbon atoms, and R^{A} represents a hydrogen atom or a monovalent hydrocarbon group having 1 to 10 carbon atoms; Ar² represents a group obtained by removing (n+1) hydrogen atoms from an aromatic ring having 6 to 30 ring atoms; R² and R³ each independently represent a halogen atom, a hydroxy group, a sulfanyl group, or an organic group having 1 to 20 carbon atoms; m is an integer of 0 to 10, wherein in a case in which m is no less than 2, a plurality of R²s are identical or different from each other; and n is an integer of 0 to 10, wherein in a case in which n is no less than 2, a plurality of R³s are identical or different from each other.

2. The radiation-sensitive resin composition according to claim 1, wherein a sum of m and n is no less than 1.

3. The radiation-sensitive resin composition according to claim 1, wherein each aromatic ring that gives Ar¹ or Ar² is an aromatic hydrocarbon ring.

4. The radiation-sensitive resin composition according to claim 1, wherein R², R³ or both represents a fluorine atom or an iodine atom.

5. The radiation-sensitive resin composition according to claim 1, wherein
R², R³, or both represents a hydroxy group or an organic group having 1 to 20 carbon atoms, and
the organic group is a group comprising an acid-labile group, a group comprising a lactone ring structure or a cyclic carbonate structure, a fluorinated alcohol group, a ketone group, or an alkoxy group.

6. A method of forming a resist pattern, the method comprising:
applying the radiation-sensitive resin composition according to claim 1 directly or indirectly on a substrate;
exposing a resist film formed by the applying; and
developing the resist film exposed.

7. The method according to claim 6, wherein a sum of m and n is no less than 1.

8. The method according to claim 6, wherein each aromatic ring that gives Ar¹ or Ar² is an aromatic hydrocarbon ring.

9. The method according to claim 6, wherein R², R³ or both represents a fluorine atom or an iodine atom.

10. The method according to claim 6, wherein
R², R³, or both represents a hydroxy group or an organic group having 1 to 20 carbon atoms, and
the organic group is a group comprising an acid-labile group, a group comprising a lactone ring structure or a cyclic carbonate structure, a fluorinated alcohol group, a ketone group, or an alkoxy group.
